(19) United States
(12) Patent Application Publication
(10) Pub. No.: US 2013/0319331 A1
(43) Pub. Date: Dec. 5, 2013

(54) VAPOR DEPOSITION PARTICLE PROJECTION DEVICE AND VAPOR DEPOSITION DEVICE

(71) Applicants: Tohru Sonoda, Osaka (JP); Shinichi Kawato, Osaka (JP); Satoshi Inoue, Osaka (JP); Satoshi Hashimoto, Osaka (JP)

(72) Inventors: Tohru Sonoda, Osaka (JP); Shinichi Kawato, Osaka (JP); Satoshi Inoue, Osaka (JP); Satoshi Hashimoto, Osaka (JP)

(73) Assignee: Sharp Kabushiki Kaisha, Osaka-shi (JP)

(21) Appl. No.: 13/985,854

(22) PCT Filed: Mar. 8, 2012
(86) PCT No.: PCT/JP2012/055941

§ 371 Date: Aug. 15, 2013

(30) Foreign Application Priority Data
Mar. 15, 2011 (JP) 2011-057258

(51) Int. Cl. H01L 51/56

(52) U.S. Cl. CPC H01L 51/56
USPC 118/720; 118/715

(57) ABSTRACT

A vapor deposition particle injection device (501) of the present invention includes: vapor deposition particle generating sections (110) and (120) for generating vapor deposition particles in the form of vapor by heating vapor deposition materials (114) and (124); and a nozzle section (170) which (i) is connected to the vapor deposition particle generating sections (110) and (120) and (ii) has an injection hole (171) from which the vapor deposition particles generated by the vapor deposition particle generating sections (110) and (120) are injected outward. The vapor deposition particle generating section (120) has a smaller capacity for the vapor deposition material than the vapor deposition particle generating section (110).

### TECHNICAL FIELD

The present invention relates to a vapor deposition particle projection device (vapor deposition particle injection device) and a vapor deposition device including the vapor deposition particle injection device as a vapor deposition source.

### BACKGROUND ART

Recent years have witnessed practical use of a flat-panel display in various products and fields. This has led to a demand for a flat-panel display that is larger in size, achieves higher image quality, and consumes less power.

Under such circumstances, great attention has been drawn to an organic EL display device that (i) includes an organic EL element which uses electroluminescence (hereinafter abbreviated to “EL”) of an organic material and that (ii) is an all-solid-state flat-panel display which is excellent in, for example, low-voltage driving, high-speed response, and self-emitting characteristics.

An organic EL display device includes, for example, (i) a substrate made up of members such as a glass substrate and TFTs (thin film transistors) provided to the glass substrate and (ii) organic EL elements provided on the substrate and connected to the TFTs.

An organic EL element is a light-emitting element capable of high-luminance light emission based on low-voltage direct-current driving, and includes in its structure a first electrode, an organic EL layer, and a second electrode stacked on top of one another in that order, the first electrode being connected to a TFT.

The organic EL layer between the first electrode and the second electrode is an organic layer including a stack of layers such as a hole injection layer, a hole transfer layer, an electron blocking layer, a luminescent layer, a hole blocking layer, an electron transfer layer, and an electron injection layer.

A full-color organic EL display device typically includes, as sub-pixels aligned on a substrate, organic EL elements of red (R), green (G), and blue (B). The full-color organic EL display device carries out an image display by, with use of TFTs, selectively causing the organic EL elements to each emit light with a desired luminance.

The organic EL elements in a light-emitting section of such an organic EL display device are generally formed by multilayer vapor deposition of organic films. In production of an organic EL display device, it is necessary to form, for each organic EL element that is a light-emitting element, at least a luminescent layer of a predetermined pattern made of an organic luminescent material which emits light of the colors.

In such formation of organic films in a predetermined pattern by multilayer vapor deposition, a method such as a vapor deposition method that uses a mask referred to as a shadow mask, an inkjet method or a laser transfer method is applicable. Among these methods, the vapor deposition method that uses a mask referred to as a shadow mask is the most common method.

In a vapor deposition method employing a mask called a shadow mask, a vapor deposition source that evaporates or sublimates a vapor deposition material is provided in a chamber inside which a reduced-pressure condition can be maintained. Then, for example, under a high-vacuum condition, the vapor deposition source is heated, and thereby evaporated or sublimated.

Such a vacuum vapor deposition method employs, as a vapor deposition source, a vapor deposition particle injection device including a heat container (called a crucible) which contains a vapor deposition material (for example, see Patent Literature 1).

FIG. 15 schematically illustrates a vapor deposition particle injection device provided in a vapor deposition device described in Patent Literature 1. Note that FIG. 15 is a modified version of FIG. 7 of Patent Literature 1, which is modified such that FIG. 7 can be easily compared with an explanatory drawing (e.g. FIG. 1) of the present invention.

The vapor deposition particle injection device includes, as shown in FIG. 15, a vapor deposition source constituted by (i) a vapor deposition particle injecting section in which nozzles for injecting vapor deposition particles are arranged in a line and (ii) a vapor deposition particle generating section for generating vapor deposition particles and supplying the vapor deposition particles to the vapor deposition particle injecting section.

The vapor deposition particle generating section is configured to generate vapor deposition particles in the form of vapor by heating a vapor deposition material with use of a heater.

The vapor deposition particles generated by the vapor deposition particle generating section are guided from an end A to an end B of the vapor deposition particle injecting section so as to be injected outward from the nozzles.

At this time, a vapor-deposited film can be formed in a desired region of a film formation substrate by depositing the vapor deposition particles onto the film formation substrate through an opening (not illustrated) in a vapor deposition mask, which opening corresponds only to the desired region.

### CITATION LIST

### Patent Literature

Patent Literature 1
Japanese Patent Application Publication, Tokukai No. 2010-13731 A (Publication Date: Jan. 21, 2010)

### SUMMARY OF INVENTION

### Technical Problem

In the vapor deposition particle generating section, the vapor deposition material is heated, as described in Patent Literature 1, by the heater provided to an outer surface of a holder covering the crucible which contains the vapor deposition material. The following description discusses how heat is conducted from the heater to the vapor deposition material. Note that, for convenience of description, this is described with reference to FIG. 2 that is an explanatory drawing of the present invention.

A vapor deposition material 114 in a crucible 113 stored in a holder 111 is heated by a heater 112 provided to an outer surface of the holder 111. Accordingly, heat is conducted from an inside wall of the crucible 113 to the vapor deposition material 114. A part of the vapor deposition material 114 which part is not in contact with the inside wall of the crucible 113 is heated by heat conduction of the material itself.

How the temperature of the material increases depends on the heat conductivity of the material, and, in general, the heat conductivity of an organic material is usually low. Therefore, it takes time for the organic material to increase in its temperature evenly. In contrast, in a case of a temperature fall, the material needs to be slowly cooled, because rapid cooling may cause (i) deformation of the holder 111 in which the crucible 113 is stored and/or (ii) bumping of the vapor deposition material 114.

Because of the above, the vapor deposition rate of the vapor deposition particle generating section illustrated in FIG. 15 shows a time profile as illustrated in a graph in FIG. 16.

The crucible 113 and the holder 111 are readily heated by the heater 112. Note, however, that only part of the vapor deposition material 114 which part is in contact with the inside wall of the crucible 113 is directly heated, and a portion which is not in contact with the inside wall is heated by heat conduction of the material itself. Further, although the vapor deposition material 114 is also heated by heat radiation from the crucible 113 and the holder 111, this is not sufficient to thoroughly heat the vapor deposition material 114 within a short period of time.

Therefore, according to a conventional vapor deposition particle injection device, the time profile in a period during which a rate is increased (temperature rise period) has a gentle slope (see FIG. 16). That is, it takes time for the vapor deposition rate to become stable (i.e., it takes time for vapor deposition to become available). Therefore, the vapor deposition rate cannot be quickly changed.

That is, when the operation of the vapor deposition particle generating section is stopped for the purpose of changing the vapor deposition rate or adding a vapor deposition material, the temperature rises or falls over a long period of time. While the temperature rises or falls, the vapor deposition material is uselessly released. This causes a decrease in use efficiency of the vapor deposition material.

The present invention has been made in view of the foregoing problem, and an object of the present invention is to provide a vapor deposition particle injection device configured such that, even when the operation of a vapor deposition particle generating section is stopped for the purpose of changing a vapor deposition rate or adding a vapor deposition material etc., a desired vapor deposition rate is quickly reached.

### Solution to Problem

In order to attain the above object, a vapor deposition particle injection device in accordance with the present invention includes: a plurality of vapor deposition particle sources for generating vapor deposition particles in the form of vapor by heating a vapor deposition material; and an injection container which (i) is connected to the plurality of vapor deposition particle sources and (ii) has an injection hole from which the vapor deposition particles generated by the plurality of vapor deposition particle sources are injected outward, assuming that a flow rate of vapor deposition particles which flow from each of the plurality of vapor deposition particle sources to the injection container is a vapor deposition rate of the each of the plurality of vapor deposition particle sources, a target vapor deposition rate of at least one of the plurality of vapor deposition particle sources being reached within a shorter time than a target vapor deposition rate of the other(s) of the plurality of vapor deposition particle sources.

According to the configuration, the target vapor deposition rate of at least one of the plurality of vapor deposition particle sources is reached within a shorter time than that of the other(s) of the plurality of vapor deposition particle sources. Therefore, when a vapor deposition rate is to be changed to a new vapor deposition rate, the new vapor deposition rate is reached first by the at least one of the plurality of vapor deposition particle sources which quickly achieves the target vapor deposition rate. This makes it possible to change the vapor deposition rate quickly.

### Advantageous Effects of Invention

A vapor deposition particle injection device in accordance with the present invention includes: a plurality of vapor deposition particle sources for generating vapor deposition particles in the form of vapor by heating a vapor deposition material; and an injection container which (i) is connected to the plurality of vapor deposition particle sources and (ii) has an injection hole from which the vapor deposition particles generated by the plurality of vapor deposition particle sources are injected outward, assuming that a flow rate of vapor deposition particles which flow from each of the plurality of vapor deposition particle sources to the injection container is a vapor deposition rate of the each of the plurality of vapor deposition particle sources, a target vapor deposition rate of at least one of the plurality of vapor deposition particle sources being reached within a shorter time than a target vapor deposition rate of the other(s) of the plurality of vapor deposition particle sources.

### BRIEF DESCRIPTION OF DRAWINGS

FIG. 1 schematically illustrates an overall configuration of a vapor deposition device including a vapor deposition particle injection device in accordance with an embodiment of the present invention.

FIG. 2 schematically illustrates a configuration of a vapor deposition particle generating section constituting the vapor deposition particle injection device shown in FIG. 1.

FIG. 3 is a block diagram schematically illustrating a vapor deposition control device for controlling vapor deposition carried out by the vapor deposition particle injection device shown in FIG. 1.

FIG. 4 is a flowchart indicating successive steps of a vapor deposition control process carried out by the vapor deposition control device shown in FIG. 3.

FIG. 5 is a cross-sectional view schematically illustrating a configuration of an organic EL display device for carrying out a RGB full-color display.

FIG. 6 is a cross-sectional view of a TFT substrate in an organic EL display device.

FIG. 7 is a flowchart illustrating a production process of an organic EL display device in the order of steps.

FIG. 8 is a graph illustrating a time profile of a vapor deposition rate of each vapor deposition particle generating section.

(a) of FIG. 9 is a graph for explaining how the time required for a vapor deposition rate to change is reduced. (b) of FIG. 9 is a graph for explaining how the time required for the vapor deposition rate to become stable is reduced.

FIG. 10 schematically illustrates an overall configuration of a vapor deposition device including a vapor deposition particle injection device in accordance with another embodiment of the present invention.

FIG. 11 is a block diagram schematically illustrating a vapor deposition control device for controlling vapor deposition carried out by the vapor deposition particle injection device shown in FIG. 10.

FIG. 12 is a flowchart indicating successive steps of a vapor deposition control process carried out by the vapor deposition control device shown in FIG. 11.

FIG. 13 is a graph illustrating time profiles of vapor deposition rates of vapor deposition particle generating sections 110a to 110d in the vapor deposition particle injection device shown in FIG. 10.

FIG. 14 schematically illustrates an overall configuration of a vapor deposition device including a vapor deposition particle injection device in accordance with a further embodiment of the present invention.

FIG. 15 schematically illustrates an overall configuration of a vapor deposition device including a vapor deposition particle injection device which includes only one typical vapor deposition particle generating section.

FIG. 16 is a graph illustrating a time profile of a vapor deposition rate of a vapor deposition particle generating section.

### DESCRIPTION OF EMBODIMENTS

### Embodiment 1

The following will discuss an embodiment of the present invention.

<Overall Configuration of Vapor Deposition Device>

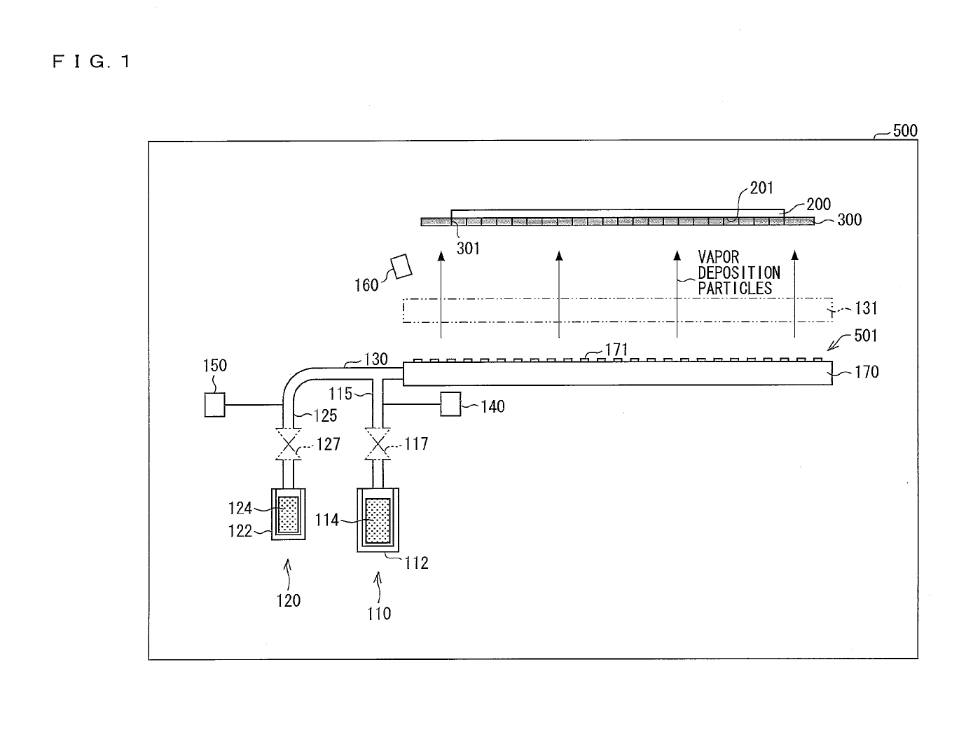

FIG. 1 schematically illustrates an overall configuration of a vapor deposition device in accordance with the present embodiment.

The vapor deposition device includes, as a vapor deposition source, a vapor deposition particle injection device 501 in a vacuum chamber 500 (see FIG. 1).

The vapor deposition particle injection device 501 includes (i) two vapor deposition particle generating sections (vapor deposition particle sources) 110 and 120 and (ii) a nozzle section (injection container) 170 having a plurality of injection holes 171.

These two vapor deposition particle generating sections 110 and 120 and the nozzle section 170 are connected to each other via pipes (connecting paths) 115, 125, and 130.

In the upper portion of the vacuum chamber 500, there are provided a vapor deposition mask 300 and a film formation substrate (film formation subject) 200 each facing toward the nozzle section 170 of the vapor deposition particle injection device 501.

The vacuum chamber 500 is provided with a vacuum pump (not illustrated) that performs vacuum-pumping of the vacuum chamber 500 via an exhaust port (not illustrated) of the vacuum chamber 500 so that a vacuum state is kept inside the vacuum chamber 500 during vapor deposition.

When the vacuum level is higher than 1.0×10⁻³ Pa, it is possible to achieve a necessary and sufficient value of a mean free path of the vapor deposition particles. Meanwhile, when the vacuum level is lower than 1.0×10⁻³ Pa, the mean free path becomes shorter. Accordingly, the vapor deposition particles are scattered. This results in a deterioration in an efficiency at which the vapor deposition particles reach the film formation substrate 200 or in a decrease in collimated components of the vapor deposition particles.

In view of the circumstances, the vacuum chamber 500 is set by the vacuum pump to have a vacuum level of not less than 1.0×10⁻⁴ Pa.

According to such a vapor deposition device, vapor deposition materials 114 and 124 are heated by heaters 112 and 122 provided to the respective two vapor deposition particle generating sections 110 and 120 so that the materials vaporize (in a case where the vapor deposition material is liquid) or sublimate (in a case where the vapor deposition material is solid). In this way, vapor deposition particles in the form of vapor are generated.

The vapor deposition particles generated by the vapor deposition particle generating sections 110 and 120 are guided via the pipes 115, 125, and 130, which are connected thereto, into the nozzle section 170. After being converged in the nozzle section 170, the vapor deposition particles are injected towards the film formation substrate 200 from the injection holes 171 which are arranged in a line.

The vapor deposition particles, which are injected outward from the vapor deposition particle injection device 501, adhere to the film formation substrate 200 after passing through the vapor deposition mask 300. The vapor deposition particles thus adhered become a vapor-deposited film on a surface of the film formation substrate 200. Note here that, since the vapor deposition particles adhere to the film formation substrate 200 after passing through the vapor deposition mask 300, an obtained vapor-deposited film is patterned in a shape.

Note that the present embodiment describes an example case in which the vapor deposition mask 300 (i) has a size corresponding to the film formation substrate 200 (e.g. the vapor deposition mask 300 has the same size as the film formation substrate 200 when viewed from above) and (ii) is closely fixed to a film formation surface 201 of the film formation substrate 200 by fixing means (not illustrated).

However, the present embodiment is not limited to such an arrangement. The vapor deposition mask 300 can be provided at a distance from the film formation substrate 200. Furthermore, the vapor deposition mask 300 can be smaller in size than a film formation region on the film formation substrate 200.

Further, the vapor deposition mask 300 can be omitted in a case where an all-over pattern of the vapor-deposited film is to be formed on the film formation substrate 200.

The vapor deposition mask 300 is optional. Therefore, the vapor deposition mask 300 may or may not be one of the constituents of the vapor deposition device.

According to the present embodiment, a scan vapor deposition is carried out for example in the following manner. While the vapor deposition particle injection device 501 is fixed and the film formation substrate 200 and the vapor deposition mask 300 are closely fixed to each other, vapor deposition is carried out by moving (scanning) the film formation substrate 200 in a direction perpendicular to a surface of a sheet on which FIG. 1 is illustrated (i.e., in a direction perpendicular to a direction along which the injection holes 171 are arranged). Alternatively, a scan vapor deposition is carried out, while the film formation substrate 200 is fixed, by moving the vapor deposition particle injection device 501 in the direction perpendicular to the direction along which the injection holes 171 are arranged.

The vapor deposition mask 300 has openings 301 (through holes) of desired shapes in desired positions. Only vapor deposition particles that have passed through the openings reach the film formation substrate 200 and form a pattern of the vapor-deposited film. In a case where a pattern is formed for each pixel, a mask (fine mask) having openings 301 which correspond to respective pixels is used. In a case where vapor deposition particles are to be deposited in an entire display region, a mask (open mask) having an opening which corresponds to the entire display region is used. An example of a film to be formed for each pixel is a luminescent layer. An example of a film to be formed in the entire display region is a hole transfer layer.

The vapor deposition particle generating sections 110 and 120 are provided with the pipes 115 and 125, respectively, for leading out generated vapor deposition particles. These pipes 115 and 125 are integrally connected to the pipe 130 which is connected to the nozzle section 170. This causes the vapor deposition particles, which are generated by the vapor deposition particle generating sections 110 and 120, to pass through the pipe 115 and the pipe 125, converge in the pipe 130, and be guided into the nozzle section 170.

The pipes 115, 125, and 130 function as connecting paths which connect the vapor deposition particle generating sections 110 and 120 with the nozzle section 170.

The pipe 115 is provided with an individual rate monitor 140 for monitoring a flow rate of vapor deposition particles (the amount of vapor deposition particles) from the vapor deposition particle generating section 110. The pipe 125 is provided with an individual rate monitor 150 for monitoring a flow rate of vapor deposition particles (the amount of vapor deposition particles) from the vapor deposition particle generating section 120.

Note here that the flow rate of vapor deposition particles flowing from the vapor deposition particle generating section 110 (or 120) to the nozzle section 170 is referred to as a vapor deposition rate of the vapor deposition particle generating section 110 (or 120).

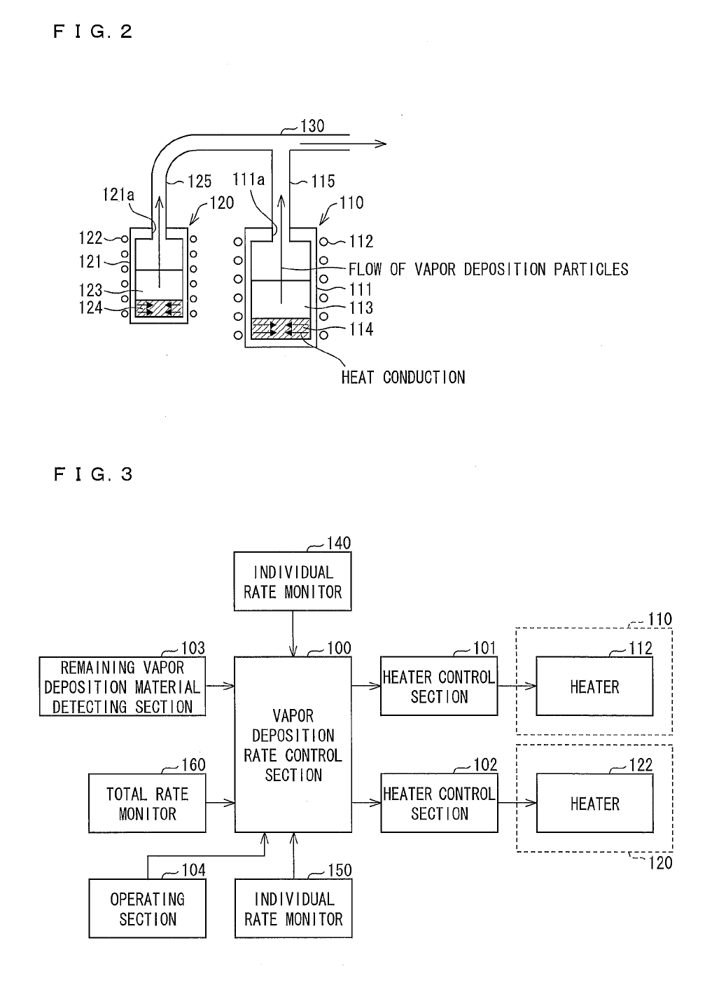

The individual rate monitor 140 is configured to measure the amount of vapor deposition particles (the flow rate of vapor deposition particles) passing through the pipe 115, which vapor deposition particles are released from a release hole 111a (see FIG. 2) in the vapor deposition particle generating section 110. The amount thus measured is the vapor deposition rate of the vapor deposition particle generating section 110.

The individual rate monitor 150 is configured to measure the amount of vapor deposition particles (the flow rate of vapor deposition particles) passing through the pipe 125, which vapor deposition particles are released from a release hole 121a (see FIG. 2) in the vapor deposition particle generating section 120. The amount thus measured is the vapor deposition rate of the vapor deposition particle generating section 120.

Further, the vapor deposition device includes a total rate monitor 160 for monitoring a total flow rate of vapor deposition particles (the total amount of vapor deposition particles).

The total rate monitor 160 measures the amount (the flow rate) of vapor deposition particles supplied from the injection holes 171 to the film formation substrate 200. The amount thus measured is the vapor deposition rate of the vapor deposition particles injecting device 501.

That is, the flow rates of vapor deposition particles supplied from the vapor deposition particle generating sections 110 and 120 are measured in real time by the individual rate monitors 140 and 150, respectively. At the same time, the total flow rate of vapor deposition particles (equivalent to the amount of vapor deposition particles to be deposited on a substrate) is also measured by the total rate monitor 160. According to the values measured by these rate monitors, heat to be applied to each of the vapor deposition particle generating sections 110 and 120 is individually controlled. This control is described later in detail.

The following description deals with configurations of the vapor deposition particle generating sections 110 and 120.

<Configurations of Vapor Deposition Particle Generating Sections>

FIG. 2 schematically illustrates overall configurations of the vapor deposition particle generating sections 110 and 120.

The vapor deposition particle generating section 110 includes (i) a holder 111, (ii) a heater 112 provided to an outer surface of the holder 111, and (iii) a crucible 113 which contains a vapor deposition material 114 and is stored in the holder 111 (see FIG. 2).

<Configuration of Holder 111>

The holder 111, which serves as a casing, contains and holds the crucible 113 therein.

The holder 111, for example, has the shape of a cylinder or a polygonal tube. There is a release hole 111a in a top surface of the holder 111, from which release hole 111a vapor deposition particles in the form of vapor are injected outward.

<Configuration of Heater 112>

The heater 112 is provided around the holder 111.

The heater 112 is constituted by a high-resistivity wire, such as a nichrome wire, which is wound around the holder 111 so that the holder 111 is heated from the outer-surface side.

Note that heating means other than the heater 112 can also be used. The heating means is, for example, electromagnetic induction etc.

<Configuration of Crucible 113>

The crucible 113 is a heat container for containing (reserving) a vapor deposition material which is to be heated. The crucible 113 used here can be an ordinary crucible which has conventionally been used in a vapor deposition source. Examples of such an ordinary crucible include those made of graphite, PBN (Pyrolytic Boron Nitride), metal, etc.

Note that the holder 111 and the crucible 113 are each preferably made of a material which has a high heat conductivity. This is because such holder 111 and crucible 113 efficiently conduct heat from the heater 112 which is provided outside the holder 111.

The heater 112 heats, via the holder 111, the crucible 113 so that the vapor deposition material 114 in the crucible 113 evaporates or sublimates into vapor (vapor deposition particles).

That is, the crucible 113 is used as a vapor deposition particle generating section which generates vapor deposition particles in the form of vapor.

The crucible 113 is provided at a bottom of the holder 111 and has a closed top surface.

The vapor deposition particles in the form of vapor are released from the release hole 111a in the holder 111, pass through the pipe 115 and then through the pipe 130, are guided to the nozzle section 170, and then are injected toward the film formation substrate 20 from the injection holes 171 in the nozzle section 170.

Meanwhile, the vapor deposition particle generating section 120 includes (i) a holder 121, (ii) a heater 122 provided to an outer surface of the holder 121, (iii) a crucible 123 which contains a vapor deposition material 124 and is stored in the holder 121 (see FIG. 2).

The heater 122 is constituted by a high-resistivity wire, such as a nichrome wire, which is wound around the holder 121. The heater 122 heats the holder 121 from the outer-surface side.

The vapor deposition material 124 contained in the crucible 123 is heated by the heater 122 provided to the outer surface of the holder 121.

There is a release hole 121a in a top surface of the holder 121, from which release hole 121a vapor deposition particles generated by heating the vapor deposition material 124 are to be injected. The release hole 121a is continuous with the pipe 125 for guiding the vapor deposition particles to the injection holes 171.

As described earlier, the pipes 115 and 125 are connected to the pipe 130. This causes the vapor deposition particles generated by the vapor deposition particle generating sections 110 and 120 to pass through the pipe 115 and the pipe 125, respectively, converge in the pipe 130, and are guided to the nozzle section 170.

As described above, the vapor deposition particle generating section 110 and the vapor deposition particle generating section 120 basically have the same configuration. However, the vapor deposition particle generating sections 110 and 120 have different capacities for a vapor deposition material. Specifically, the vapor deposition particle generating section 120 has a small capacity for the vapor deposition material 124, as compared to the capacity for the vapor deposition material 114 that the vapor deposition particle generating section 110 has. When the capacity for a vapor deposition material is small like above, heat is conducted readily to the entire vapor deposition material. Therefore, a desired vapor deposition rate is easily reached. In other words, a vapor deposition particle generating section having a smaller capacity for a vapor deposition material achieves a desired vapor deposition rate more quickly.

As described above, a difference in time required for a desired vapor deposition rate to be reached, which difference results from a difference in capacity for a vapor deposition material, is utilized, whereby it is possible to quickly change the vapor deposition rate.

The following describes a control block diagram and a flow of a control process each for controlling vapor deposition in the vapor deposition device in accordance with the present embodiment.

<Vapor Deposition Control Block Diagram>

FIG. 3 is a control block diagram of the vapor deposition particle injection device 501 for carrying out the vapor deposition control.

The vapor deposition particle injection device 501 includes a control section for controlling vapor deposition, which is constituted by (i) a vapor deposition rate control section 100 for carrying out main control, (ii) a heater control section 101 for controlling supply of a drive current to the heater 112 of the vapor deposition particle generating section 110, and (iii) a heater control section 102 for controlling supply of a drive current to the heater 122 of the vapor deposition particle generating section 120 (see FIG. 3).

The vapor deposition rate control section 100 is configured to: receive (i) data (monitor result) from the individual rate monitor 140 which monitors a vapor deposition rate of the vapor deposition particle generating section 110, (ii) data (monitor result) from the individual rate monitor 150 which monitors a vapor deposition rate of the vapor deposition particle generating section 120, (iii) data (monitor result) from the total rate monitor 160 which monitors a vapor deposition rate of the entire vapor deposition device, (iv) data (detection result) from a remaining vapor deposition material detecting section 103 which detects the amount of a vapor deposition material remaining in the vapor deposition particle generating section 110 and the amount of a vapor deposition material remaining in the vapor deposition particle generating section 120, and (v) data (set vapor deposition rate) inputted via an operating section 104; and output control instruction signals to the heater control section 101 and the heater control section 102 in accordance with the data thus received.

The data (monitor result) received from the individual rate monitor 140 is, for example, a value obtained by measuring the flow rate of vapor deposition particles from the vapor deposition particle generating section 110. The vapor deposition rate control section 100 determines whether or not the vapor deposition rate of the vapor deposition particle generating section 110 has reached a desired vapor deposition rate (set vapor deposition rate) by comparing the data received from the individual rate monitor 140 with the data (set vapor deposition rate) received from the operating section 104.

Similarly, the data (monitor result) received from the individual rate monitor 150 is, for example, a value obtained by measuring the flow rate of vapor deposition particles from the vapor deposition particle generating section 120. The vapor deposition rate control section 100 determines whether or not the vapor deposition rate of the vapor deposition particle generating section 120 has reached a desired vapor deposition rate (set vapor deposition rate) by comparing the data received from the individual rate monitor 150 with the data (set vapor deposition rate) received from the operating section 104.

Further, with the assumption that the data received from the total rate monitor 160 (monitor result) is a value obtained by measuring the flow rate of vapor deposition particles in the entire vapor deposition particle injection device 501, the vapor deposition rate control section 100 determines whether or not the value thus measured has reached a desired vapor deposition rate (set vapor deposition rate) by comparing the value with the data (set vapor deposition rate) received from the operating section 104.

The vapor deposition rate control section 100 further determines whether or not the operation (generation of vapor deposition particles) of the vapor deposition particle generating section 110 or the vapor deposition particle generating section 120 is to be stopped, in accordance with the detection result received from the remaining vapor deposition material detecting section 103.

Next, the description below deals with a flow of a vapor deposition control process in the vapor deposition rate control section 100.

<Vapor Deposition Control Process Flowchart>

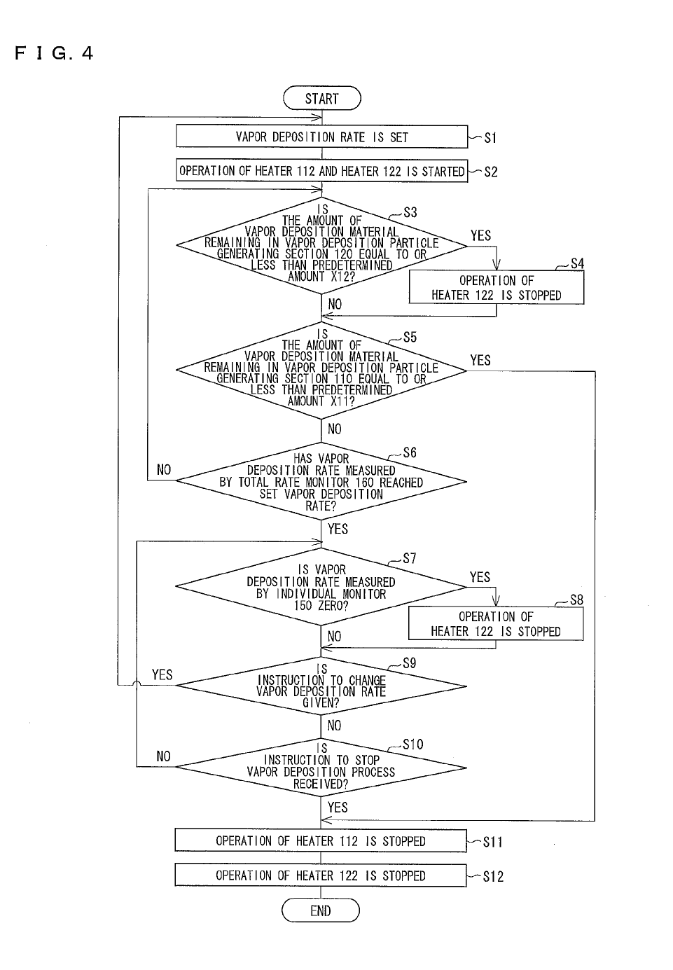

FIG. 4 is a flowchart indicating successive steps of a vapor deposition control process carried out in the vapor deposition rate control section 100.

First, a vapor deposition rate for the vapor deposition particle injection device 501 is set (S1). Note here that the vapor deposition rate control section 100 receives information indicative of a desired vapor deposition rate from the operating section 104, and sets the vapor deposition rate according to the information thus received.

Next, the heater 112 and the heater 122 start being operated (S2). Note here that the vapor deposition rate control section 100 sends, to the heater control section 101 and the heater control section 102, drive signals for causing the heater 112 of the vapor deposition particle generating section 110 and the heater 122 of the vapor deposition particle generating section 120 to operate so that the set vapor deposition rate is reached. The heater control section 101 and the heater control section 102, which received the drive signals, carry out a control such that the drive currents are supplied to the heaters 112 and 122, respectively. This causes the heater 112 and the heater 122 to operate.

Next, it is determined whether or not the amount of a vapor deposition material remaining in the vapor deposition particle generating section 120 and the amount of a vapor deposition material remaining in the vapor deposition particle generating section 110 are not more than a predetermined amount X12 and not more than a predetermined amount X11, respectively (S3 and S5). Note here that the vapor deposition rate control section 100 checks the detection result received from the remaining vapor deposition material detecting section 103, and determines whether or not the amount of the vapor deposition material remaining in the vapor deposition particle generating section 120 and the amount of the vapor deposition material remaining in 110 are equal to or less than the predetermined amounts X12 and X11, respectively.

In a case where the amount of the vapor deposition material remaining in the vapor deposition particle generating section 120 is not more than the predetermined amount X12 in S3, the heater control section 102 stops the operation of the heater 122 (S4).

On the other hand, in a case where the amount of the vapor deposition material remaining in the vapor deposition particle generating section 110 is not more than X11 in S5, the heater control section 101 stops the operation of the heater 112, and the heater control section 102 also stops the operation of the heater 122. This ends the vapor deposition process (S11 and S12). Note here that the vapor deposition rate control section 100 sends, in response to a signal received from the operating section 104 which signal indicates that the vapor deposition process is to be stopped, instruction signals to the heater control sections 101 and 102 which instruction signals are to stop the supply of currents to the heater 112 and the heater 122. This stops the operation of the vapor deposition particle generating sections 110 and 120.

The predetermined amounts X12 and X11 are such amounts that the vapor deposition rates of the vapor deposition particle generating section 120 and the vapor deposition particle generating section 110, respectively, cannot be controlled. Further, the predetermined amounts X12 and X11 are such amounts that vapor deposition cannot be continued. In a case where the amount of the vapor deposition material is not more than the predetermined amount X12 (or X11), the crucible 123 (or 113) of the vapor deposition particle generating section 120 (or 110) will be heated with no material left therein. This may cause a problem.

Therefore, in a case where the amounts of the vapor deposition materials remaining in the vapor deposition particle generating sections 120 and 110 are more than the predetermined amounts X12 and X11, respectively, the process proceeds to S6, where it is determined whether or not the vapor deposition rate of the vapor deposition device has reached the vapor deposition rate which was set in S1. That is, in S6, the vapor deposition rate control section 100 determines whether or not the vapor deposition rate has reached the set vapor deposition rate from the data (monitor result) received from the total rate monitor 160.

In a case where the vapor deposition rate control section 100 determines that the vapor deposition rate has not reached the set vapor deposition rate in S6, the process returns to S3 and S4. Then, the vapor deposition rate control section 100 determines whether or not the amounts of the vapor deposition particles remaining in the vapor deposition particle generating sections 120 and 110 are equal to or less than the predetermined amount X12 and X11, respectively.

On the other hand, in a case where the vapor deposition rate control section 100 determines that the vapor deposition rate has reached the set vapor deposition rate in S6, the process proceeds to S7. Then, the vapor deposition rate control section 100 determines whether there are vapor deposition particles coming from the vapor deposition particle generating section 120. That is, in S7, the vapor deposition rate control section 100 determines, from the data (monitor result) received from the individual rate monitor 150, whether any of vapor deposition particles are supplied from the vapor deposition particle generating section 120. In a case where the vapor deposition rate measured by the individual rate monitor 150 is 0, the heater control section 102 stops the operation of the heater 122 (S8). Note here that, of the vapor deposition particle generating sections 120 and 110, the operation of the vapor deposition particle generating section 120 only is stopped so that only the vapor deposition particle generating section 110 keeps operating. On the other hand, in a case where the vapor deposition rate measured by the individual rate monitor 150 is not 0 in S7, the process proceeds to S9.

In S9, the vapor deposition rate control section 100 determines whether or not an instruction is given to change the vapor deposition rate. That is, the vapor deposition rate control section 100 monitors whether or not an instruction is given to change the vapor deposition rate, while the vapor deposition process is stably carried out by the vapor deposition particle generating sections 120 and 110.

In a case where the vapor deposition rate control section 100 receives, while monitoring whether or not an instruction is given to change the vapor deposition rate in S9, a signal indicating that an instruction was given to change the vapor deposition rate, the process returns to S1. Then, the vapor deposition rate is set to a new vapor deposition rate and then the processes from S2 to S9 are carried out.

On the other hand, in a case where no instruction was given to change the vapor deposition rate in the vapor deposition rate control section 100 in S9, the process proceeds to S10. Then, the vapor deposition rate control section 100 determines whether or not an instruction to stop the vapor deposition process is received (S10).

In a case where the vapor deposition rate control section 100 determines that the instruction to stop the vapor deposition process has not been received in S10, the process returns to S7. Then, the vapor deposition rate control section 100 checks the vapor deposition rate measured by the individual rate monitor 150.

On the other hand, in a case where it is determined that the instruction to stop the vapor deposition process has been received in S10, the operations of the heaters 112 and 122 are stopped (S11 and S12). This ends the vapor deposition process. Note here that the vapor deposition rate control section 100 sends, in response to a signal supplied from the operating section 104 which signal indicates that the vapor deposition process is to be stopped, instruction signals to the heater control sections 101 and 102, which instruction signals are to stop the supply of currents to the heater 112 and the heater 122. This stops the operations of the vapor deposition particle generating sections 110 and 120.

The following description deals with an organic EL display device produced with the use of the foresaid vapor deposition device and the method for producing the organic EL display device.

### <Overall Configuration of Organic EL Display Device>

The description first deals with the overall configuration of the organic EL display device.

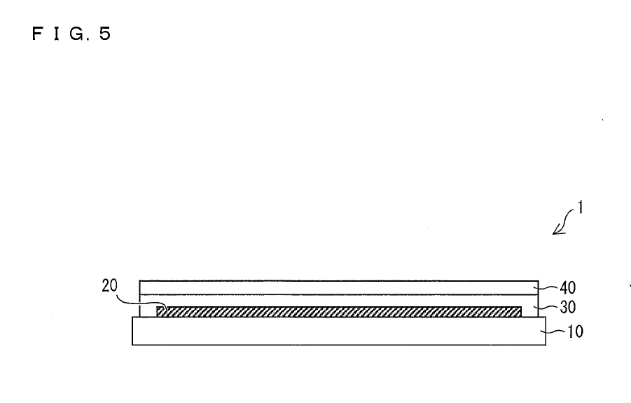

FIG. 5 is a cross-sectional view schematically illustrating a configuration of the organic EL display device 1 that carries out an RGB full color display.

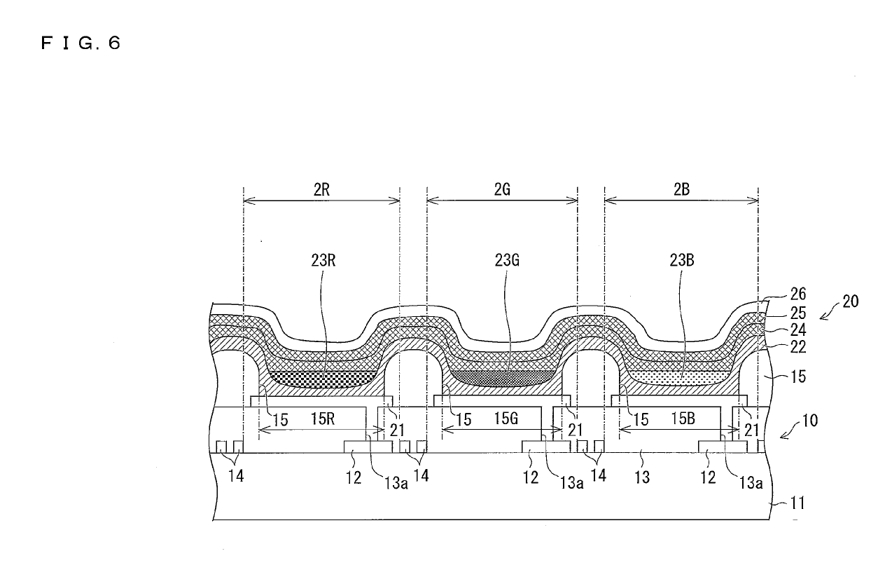

As illustrated in FIG. 5, the organic EL display device 1 produced in the present embodiment includes: a TFT substrate 10 including TFTs 12 (see FIG. 6); organic EL elements 20 provided on the TFT substrate 10 and connected to the TFTs 12; an adhesive layer 30; and a sealing substrate 40 arranged in that order.

The organic EL elements 20, as illustrated in FIG. 5, are contained between the TFT substrate 10 and the sealing substrate 40 by attaching the TFT substrate 10, on which the organic EL elements 20 are provided, to the sealing substrate 40 with use of the adhesive layer 30.

The organic EL display device 1, in which the organic EL elements 20 are contained between the TFT substrate 10 and the sealing substrate 40 as described above, prevents infiltration of oxygen, moisture and the like present outside into the organic EL elements 20.

The following describes in detail respective configurations of the TFT substrate 10 and each of the organic EL elements 20 both included in the organic EL display device 1.

<Configuration of TFT Substrate 110>

FIG. 6 is a cross sectional view schematically illustrating a configuration of the organic EL elements 20 constituting a display section of the organic EL display device 1.

The TFT substrate 10, as illustrated in FIG. 6, includes on a transparent insulating substrate 11 such as a glass substrate: TFTs 12 (switching elements); wires 14; an interlayer film 13; edge covers 115; and the like.

The organic EL display device 1 is a full-color active matrix organic EL display device. The organic EL display device 1 includes, on the insulating substrate 11 and in regions defined by the wires 14, pixels 2R, 2G, and 2B arranged in a matrix manner which include organic EL elements 20 of red (R), green (G), and blue (B), respectively.

The TFTs 12 are provided so as to correspond respectively to the pixels 2R, 2G, and 2B. Since the configuration of a TFT has conventionally been well-known, the individual layers of a TFT 12 are not illustrated in the drawings or described herein.

The interlayer insulating film 13 is provided on the insulating substrate 11 throughout the entire region of the insulating substrate 11 to cover the TFTs 12 and the wires 14.

There are provided on the interlayer insulating film 13 first electrodes 21 of the organic EL elements 20.

The interlayer insulating film 13 has contact holes 13a for electrically connecting the first electrodes 21 of the organic EL elements 20 to the TFTs 12. This electrically connects the TFTs 12 to the organic EL elements 20 via the contact holes 13a.

The edge covers 15 are each an insulating layer for preventing the first electrode 21 and a second electrode 26 of a corresponding one of the organic EL elements 20 from short-circuiting with each other due to, for example, (i) a reduced thickness of an organic EL layer in an edge section of the first electrode 21 or (ii) an electric field concentration

Each of the edge covers 15 is so formed on the interlayer insulating film 13 as to cover edge sections of the first electrode 21.

As illustrated in FIG. 6, the first electrode 21 is exposed in an area where the first electrode 21 is not covered with the edge cover 15. This area that is exposed serves as a light-emitting section of each of the pixels 2R, 2G, and 2B.

The pixels 2R, 2G, and 2B are, in other words, isolated from one another by the insulating edge covers 15. The edge covers 15 thus function as an element isolation films as well.

<Production Method of TFT Substrate 10>

The insulating substrate 11 can be made of, for example, alkali-free glass or plastic. Embodiment 1 employs an alkali-free glass substrate having a thickness of 0.7 mm.

A known photosensitive resin can be used for each of the interlayer insulating film 13 and the edge cover 15. Examples of such a known photosensitive resin encompass an acrylic resin and a polyimide resin.

Further, the TFTs 12 are fabricated by a known method. Embodiment 1 describes, as an example, the active matrix organic EL display device 1 in which the TFTs 12 are respectively formed in the pixels 2R, 2G and 2B, as described above.

However, Embodiment 1 is not limited to such a configuration. The present invention is also applicable to production of a passive matrix organic EL display device in which any TFT is not formed.

<Configuration of Organic EL Elements 20>

Each of the organic EL elements 20 is a light-emitting element capable of high-luminance light emission based on low-voltage direct-current driving, and includes: the first electrode 21; the organic EL layer; and the second electrode 26, provided on top of one another in that order.

The first electrodes 21 are each a layer having the function of injecting (supplying) positive holes into the organic EL layer. The first electrodes 21 are, as described above, connected to the TFTs 12 via the contact holes 13a.

The organic EL layer provided between the first electrodes 21 and the second electrode 26 includes, for example, as illustrated in FIG. 6: a hole injection layer/hole transfer layer 22; luminescent layers 23R, 23G, and 23B; an electron transfer layer 24; and an electron injection layer 25, formed in that order from the first electrode 21 side.

Note that the organic EL layer can, as needed, further include a carrier blocking layer (not illustrated) for blocking a flow of carriers such as holes and electrons. Further, a single layer can have a plurality of functions. For example, a single layer that serves as both a hole injection layer and a hole transfer layer may be formed.

The above stack order intends to use (i) the first electrode 21 as an anode and (ii) the second electrode 26 as a cathode. The stack order of the organic EL layer is reversed in the case where the first electrode 21 serves as a cathode and the second electrode 26 serves as an anode.

The hole injection layer has the function of increasing efficiency in injecting positive holes into the organic EL layer from the first electrode 121. The hole transfer layer has the function of increasing efficiency in transferring positive holes to the luminescent layers 23R, 23G, and 23B. The hole injection layer/hole transfer layer 22 is so formed uniformly throughout the entire display region of the TFT substrate 10 as to cover the first electrodes 21 and the edge covers 15.

The present embodiment is configured to involve, as the hole injection layer and the hole transfer layer, a hole injection layer/hole transfer layer 22 that integrally combines a hole injection layer with a hole transfer layer as described above. The present embodiment is, however, not limited to such an arrangement. The hole injection layer and the hole transfer layer may be provided as separate layers independent of each other.

There are provided on the hole injection layer/hole transfer layer 22 the luminescent layers 23R, 23G, and 23B formed in correspondence with the respective pixels 2R, 2G, and 2B.

The luminescent layers 23R, 23G, and 23B are each a layer that has the function of emitting light by recombining (i) positive holes injected from the first electrode 21 side with (ii) electrons injected from the second electrode 26 side. The luminescent layers 23R, 23G, and 23B are each made of a material with high luminous efficiency, such as a low-molecular fluorescent dye and a metal complex.

The electron transfer layer 24 is a layer that has the function of increasing efficiency in transferring electrons to the luminescent layers. The electron injection layer 25 is a layer that has the function of increasing efficiency in injecting electrons from the second electrode 26 into the organic EL layer.

The electron transfer layer 24 is so provided on the luminescent layers 23R, 23G, and 23B and the hole injection layer/hole transfer layer 22 uniformly throughout the entire display region of the TFT substrate 10 as to cover the luminescent layers 23R, 23G, and 23B and the hole injection layer/hole transfer layer 22.

The electron injection layer 25 is so provided on the electron transfer layer 24 uniformly throughout the entire display region of the TFT substrate 10 as to cover the electron transfer layer 24.

The electron transfer layer 24 and the electron injection layer 25 may be provided either (i) as separate layers independent of each other as described above or (ii) integrally with each other. In other words, the organic EL display device 1 may include an electron transfer layer/electron injection layer instead of the electron transfer layer 24 and the electron injection layer 25.

The second electrode 26 is a layer having the function of injecting electrons into the organic EL layer including the above organic layers. The second electrode 26 is so provided on the electron injection layer 25 uniformly throughout the entire display region of the TFT substrate 10 as to cover the electron injection layer 25.

The organic layers other than the luminescent layers 23R, 23G, and 23B are not essential for the organic EL layer, and may thus be included as appropriate in accordance with a required property of the organic EL element 20.

Further, like the hole injection layer/hole transfer layer 22 and the electron transfer layer/electron injection layer, a single layer can have a plurality of functions.

The organic EL layer may further include a carrier blocking layer according to need. The organic EL layer can, for example, additionally include, as a carrier blocking layer, a hole blocking layer between the luminescent layers 23R, 23G, and 23B and the electron transfer layer 24 to prevent positive holes from transferring from the luminescent layers 23R, 23G, and 23B to the electron transfer layer 24 and thus to improve luminous efficiency.

In the above arrangement, layers other than the first electrodes 21 (anode), the second electrode 26 (cathode) and the luminescent layers 23R, 23G and 23B may be provided as needed.

<Method for Producing Organic EL Element 20>

The first electrodes 21 are formed by (i) depositing an electrode material by a method such as sputtering and (ii) then patterning the electrode material in shapes for respective pixels 2R, 2G, and 2B by photolithography and etching.

The first electrodes 21 can be made of any of various electrically conductive materials. Note, however, that the first electrodes 21 need to be transparent or semi-transparent in a case where the organic EL display device includes a bottom emission organic EL element in which light is emitted towards an insulating substrate 11 side.

Meanwhile, a second electrode 26 needs to be transparent or semi-transparent in a case where the organic EL display device includes a top emission organic EL element in which light is emitted from a side opposite to the substrate side.

The conductive film material for each of the first electrodes 21 and the second electrode 26 is, for example, (i) a transparent conductive material such as ITO (Indium Tin Oxide), IZO (indium zinc oxide), and gallium-added zinc oxide (GZO) or (ii) a metal material such as gold (Au), nickel (Ni), and platinum (Pt).

The above conductive film can be formed by, instead of the sputtering method, a method such as a vacuum vapor deposition method, a chemical vapor deposition (CVD) method, a plasma CVD method, and a printing method. For example, the vapor deposition device according to the present embodiment (described later) can be used for formation of layers of the first electrodes 21.

The organic EL layer can be made of a known material. Note that each of the luminescent layers 23R, 23G, and 23B can be made of a single material or made of a host material mixed with another material as a guest material or a dopant.

The hole injection layer, the hole transfer layer, or the hole injection layer/hole transfer layer 22 can be made of a material such as (i) anthracene, azatriphenylene, fluorenone, hydrazone, stilbene, triphenylene, benzine, styryl amine, triphenylamine, porphyrin, triazole, imidazole, oxadiazole, oxazole, polyarylalkane, phenylenediamine, arylamine, or a derivative of any of the above, or (ii) a monomer, an oligomer, or a polymer of an open chain conjugated system or cyclic conjugated system, such as a thiophene compound, a polysilane compound, a vinylcarbazole compound, or an aniline compound.

The luminescent layers 23R, 23G, and 23B are each made of a material, such as a low-molecular fluorescent pigment or a metal complex, that has high light emission efficiency. For example, the luminescent layers 23R, 23G, and 23B are each made of a material such as anthracene, naphthalene, indene, phenanthrene, pyrene, naphthacene, triphenylene, perylene, picene, fluoranthene, acephenanthrylene, pentaphene, pentacene, coronene, butadiene, coumarin, acridine, stilbene, a derivative of any of the above, a tris(8-hydroxyquinolinate) aluminum complex, a bis(benzohydroxyquinolinate) beryllium complex, a tri(dibenzoylmethyl) phenanthroline europium complex, ditoluyl vinyl biphenyl, hydroxyphenyl oxazole, or hydroxyphenyl thiazole.

The electron transfer layer 24, the electron injection layer 25, or the electron transfer layer/electron injection layer can be made of a material such as a tris(8-hydroxyquinolinate) aluminum complex, an oxadiazole derivative, a triazole derivative, a phenylquinoxaline derivative, or a silole derivative.

### <Method for Forming Film Pattern by Vacuum Vapor Deposition Method>

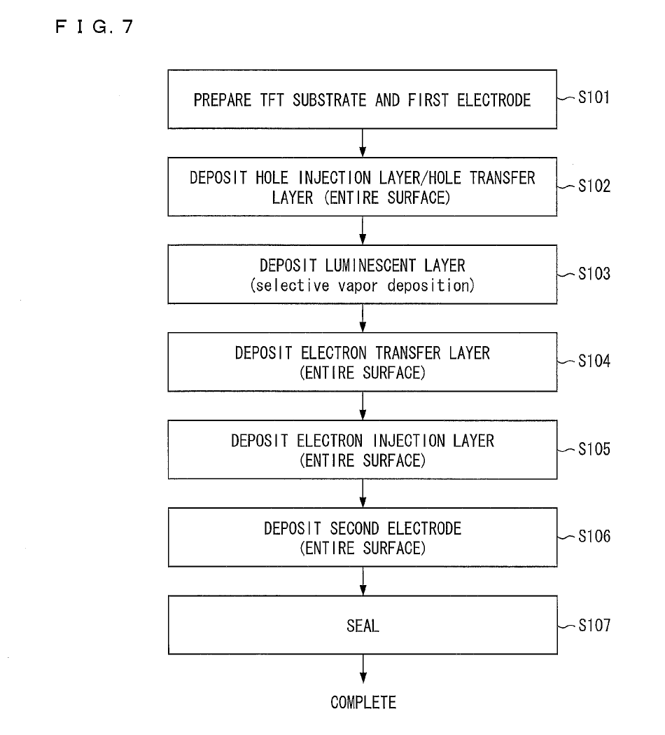

The following discusses a method for forming a film pattern by a vacuum vapor deposition method, mainly with reference to FIG. 7.

Note that the following description deals with an example case where: the TFT substrate 10 is used as the film formation substrate (film formation subject); an organic luminescent material is used as the vapor deposition material; and an organic EL layer is formed as a vapor-deposited film, by the vacuum vapor deposition method, on the film formation substrate on which the first electrodes 21 are formed.

As described above, the organic EL display device 1 that is a full-color organic display device includes, for example, the pixels 2R, 2G, and 2B arranged in a matrix manner, which pixels 2R, 2G, and 2B are respectively made of the organic EL elements 20 of red (R), green (G), and blue (B) that include the luminescent layers 23R, 23G, and 23B, respectively.

It is needless to say that the organic EL elements 20 may alternatively include, for example, luminescent layers of cyan (C), magenta (M), and yellow (Y), respectively, or luminescent layers of red (R), green (G), blue (B), and yellow (Y), respectively, in place of the luminescent layers 23R, 23G, and 23B of red (R), green (G), and blue (B).

Such an organic EL display device 1 performs a color image display by selectively causing the organic EL elements 20 to emit light at a desired luminance by use of the TFTs 12.

Therefore, for producing the organic EL display device 1, it is required to form, on the film formation substrate, the luminescent layers that are made of organic luminescent materials emitting respective colors. At this time, the luminescent layers each need to be formed in a predetermined pattern for each organic EL element 20.

As described above, in the vapor deposition mask 300, the openings 301 each are formed in a desired shape at a desired position. As illustrated in FIGS. 1 through 3, the vapor deposition mask 300 is fixed to the film formation surface 201 of the film formation substrate 200 so as to be in close contact with the film formation surface 201.

On an opposite side of the vapor deposition mask 300 with respect to the film formation substrate 200, the vapor deposition particle injection device 501 is provided as a vapor deposition source so as to face the film formation surface 201 of the film formation substrate 200.

When the organic EL display device 1 is to be produced, the organic luminescent material is heated under high vacuum so that the organic luminescent material turned into gas by evaporation or sublimation, and then injected in the form of the vapor deposition particle in a gas phase from the injection holes 171 in the nozzle section 170.

The vapor deposition material injected as the vapor deposition particles from the injection holes 171 in the nozzle section 170 is deposited onto the film formation substrate 200 through the openings 301 in the vapor deposition mask 300.

This makes it possible to form, as a vapor-deposited film, an organic film having a desired film pattern only in a desired position, corresponding to each of the openings 301 in the vapor deposition mask 300, on the film formation substrate 200. Note that the vapor deposition is separately carried out for each color of the luminescent layers (This is called a “selective vapor deposition”).

For example, in case of the hole injection layer/hole transfer layer 22 as illustrated in FIG. 6, a film is formed throughout an entire area of the display section. Therefore, film formation is carried out by using, as the vapor deposition mask 300, an open mask that has an opening only in positions corresponding to the entire area of the display section and a region where film formation is required.

Note that the same applies to the electron transfer layer 24, the electron injection layer 25, and the second electrode 26.

Meanwhile, film formation is carried out for the luminescent layer 23R of a pixel in FIG. 6 that performs a red display, film formation is carried out by using, as the vapor deposition mask 300, a fine mask which has an opening only in a position corresponding to a region where a red luminescent material is to be vapor-deposited.

<Process Flow in Production of Organic EL Display Device>

FIG. 7 is a flowchart illustrating a production process of the organic EL display device 1 in the order of steps.

First, the TFT substrate 10 is prepared. On thus prepared TFT substrate 10, the first electrodes 21 are formed (step S101). Note that the TFT substrate 10 can be prepared by a known technique.

Then, on this TFT substrate 10 on which the first electrodes 21 are formed, the hole injection layer and the hole transfer layer are formed throughout an entire pixel region by the vacuum vapor deposition method, with use of an open mask as the vapor deposition mask 300 (step S102). Note that the hole injection layer and the hole transfer layer can alternatively be formed as the hole injection layer/hole transfer layer 22 as described earlier.

Next, selective vapor deposition of each of the luminescent layers 23R, 23G, and 23B is carried out by the vacuum vapor deposition method with use of a fine mask as the vapor deposition mask 300 (step S103). Thereby, patterned films are formed so as to correspond to the pixels 2R, 2G, 2B, respectively.

Subsequently, on the TFT substrate 10 on which the luminescent layers 23R, 23G, and 23B are formed, the electron transfer layer 24, the electron injection layer 25, and the second electrode 26 each are formed in this order throughout the entire pixel region by the vacuum vapor deposition method, with use of an open mask as the vapor deposition mask 300 (steps S104 to S106).

For the TFT substrate 10 on which vapor deposition has been completed as described above, sealing of a region (display section) of the organic EL elements 20 is performed so as to prevent the organic EL elements 20 from deteriorating due to moisture or oxygen in the air (step S107).

This sealing can be performed, for example, by a method (e.g., CVD method) in which a film that does not easily allow moisture and oxygen to pass through the film, or a method in which a glass substrate or the like is bonded with an adhesive or the like.

The organic EL display device 1 is prepared in the process as described above. Such an organic EL display device 1 causes current to flow into the organic EL elements 20 in respective individual pixels from an externally provided drive circuit so that the organic EL elements 20 emit light. Thereby, the organic EL display device 1 performs a desired display.

The following describes operation of and effects brought about by a vapor deposition device in accordance with the present embodiment.

<Regarding Operation and Effect>

Generally, the time from when a vapor deposition material is evaporated to be vapor deposition particles to when the speed (vapor deposition rate) of the vapor deposition particles reaches a speed (vapor deposition rate) at which the vapor deposition particles stably form a vapor-deposited film on a film formation substrate increases in proportion to the capacity for the vapor deposition material. This is because, if the capacity for the vapor deposition material is large, it takes a long time for the vapor deposition material to be thoroughly heated, and thus more time is required for the vapor deposition material, which evaporated into vapor deposition particles, to be injected stably.

In view of the circumstances, the vapor deposition particle generating section 120 used here has a smaller capacity for a vapor deposition material than the vapor deposition particle generating section 110 does. With this, the vapor deposition material contained in the vapor deposition particle generating section 120 is thoroughly heated within a shorter period of time than that contained in the vapor deposition particle generating section 110.

This makes it possible to reduce the time from when vapor deposition starts to when a set vapor deposition rate is reached.

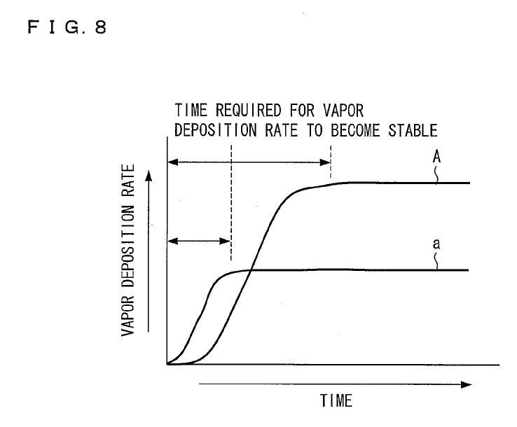

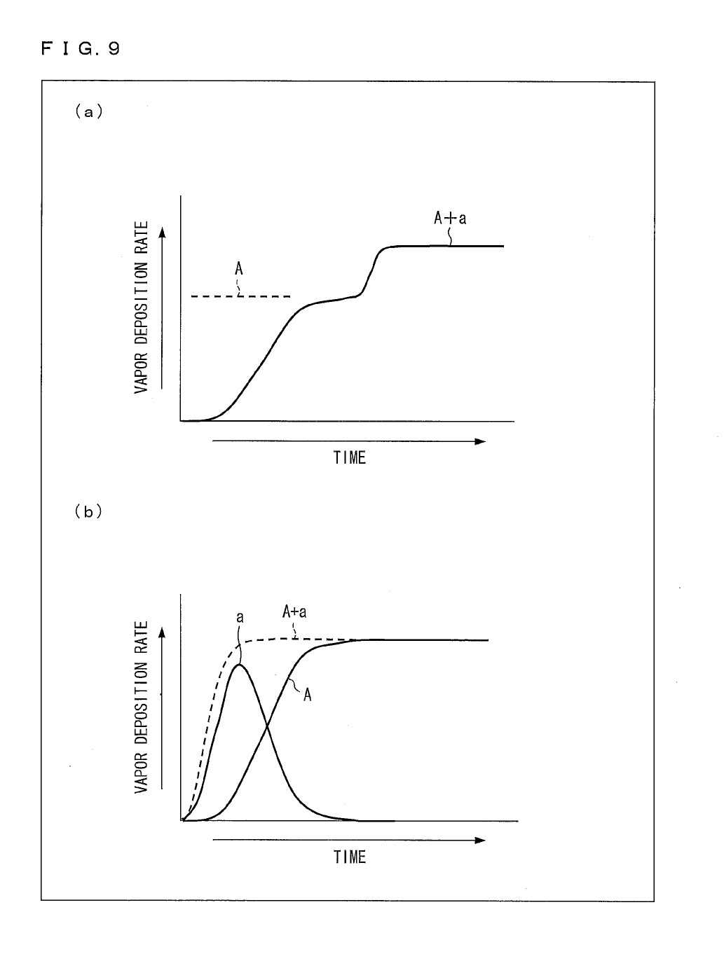

This is clear also from the graph in FIG. 8.

FIG. 8 is a graph illustrating a time profile of a vapor deposition rate of each vapor deposition particle generating section. In FIG. 8, “A” indicates the vapor deposition particle generating section 110, and “a” indicates the vapor deposition particle generating section 120.

The graph in FIG. 8 shows that the time required for the vapor deposition rate to reach a certain rate and become stable is shorter in the vapor deposition particle generating section 120 than in the vapor deposition particle generating section 110. Note that, in FIG. 8, for convenience of description, the target vapor deposition rate of the vapor deposition particle generating section 120 is lower; however, the vapor deposition rate that the vapor deposition particle generating section 120 can achieve is the same as that of the vapor deposition particle generating section 110.

Another option is to rapidly increase heat quantity (the speed at which the temperature of a heater increases) in order to accelerate the speed at which the vapor deposition rate increases and thereby reduce the time required for the certain rate to be reached. However, if the heat quantity is large, the vapor deposition material in the vicinity of the inside wall of the crucible in the vapor deposition particle generating section is excessively heated. This may cause a deterioration of the vapor deposition material, bumping of the vapor deposition material (a lump of the vapor deposition material pops out from an injection hole), and/or a deformation and damage of constituents of the vapor deposition source. Therefore, there is an upper limit on the heat quantity.

In view of the circumstances, the vapor deposition device of the present embodiment (i) includes a plurality of vapor deposition particle generating sections and (ii) at least one of the plurality of vapor deposition particle sources has a smaller capacity for the vapor deposition material than the other(s) of the plurality of vapor deposition particle sources. This makes it possible to accelerate the speed at which a vapor deposition rate increases and to reduce the time required for a target vapor deposition rate to be reached, without having to take into consideration the upper limit of the heat quantity.

According to the above arrangement, it is possible to reduce the time required for the vapor deposition rate to change to a new vapor deposition rate and to reduce the time required for the vapor deposition rate to become stable.

<Effect of Reduction in Time Required for Vapor Deposition Rate to Change>

(a) of FIG. 9 is a graph for explaining how the time required for the vapor deposition rate to change to a new vapor deposition rate is reduced. (b) of FIG. 9 is a graph for explaining how the time required for the vapor deposition rate to become stable is reduced.

The following description first deals with how the time required for the vapor deposition rate to change to the new vapor deposition rate is reduced, with reference to (a) of FIG. 9.

Note here that the vapor deposition rate is to be changed in a case where, for example, (i) a different type of an organic EL display device is to be produced and, because of process tact, the vapor deposition rate needs to be changed or (ii) one layer is to be formed from a single material whereas another layer is to be formed from a combination of that single material and another material by codeposition, and the mixing ratio of that single material to the another material needs to be controlled.

In such cases, (i) vapor deposition is first carried out with use of the vapor deposition particle generating section 110 (vapor deposition particle generating section A) and (ii) the vapor deposition particle generating section 120 (vapor deposition particle generating section a) is used to increase the vapor deposition rate. Since the vapor deposition rate of the vapor deposition particle generating section a increases quickly, the desired vapor deposition rate is reached more quickly than a case where the vapor deposition rate is increased only with the use of the vapor deposition particle generating section A.

Such an arrangement makes it possible to quickly stabilize the vapor deposition rate even in a case where the vapor deposition rate needs to be increased.

Meanwhile, in general, it is not possible to form a film on a film formation substrate until the vapor deposition rate becomes stable. Therefore, during this time, the vapor deposition material is uselessly consumed. That is, in a case where the vapor deposition rate is changed only with the use of the vapor deposition particle generating section 110 which is a main vapor deposition particle generating section A, it is not possible to form a film on the film formation substrate until the vapor deposition rate becomes stable. Therefore, during this time, the vapor deposition material is uselessly consumed.

In this regard, according to the arrangement of the present embodiment, there is provided the vapor deposition particle generating section 120 (sub-vapor deposition particle generating section a) which has a smaller capacity for a vapor deposition material than the vapor deposition particle generating section 110 (the main vapor deposition particle generating section A). This makes it possible to utilize the vapor deposition material which is otherwise wasted in the vapor deposition particle generating section 110, and thus possible to reduce the loss of the vapor deposition material and improve material use efficiency.

On the other hand, in a case where the vapor deposition rate is to be reduced, this is achieved in a similar manner. It is only necessary to (i) first carry out vapor deposition with the use of both of the vapor deposition particle generating sections and (ii) stop the heating of the vapor deposition particle generating section a whenever the vapor deposition rate is desired to be reduced.

In addition, a target vapor deposition rate in the vapor deposition particle generating section 120 is reached within a shorter time than in the vapor deposition particle generating section 110. This makes it possible to quickly change the vapor deposition rate.

Note that, as shown by dash-dot-dot lines in FIG. 1, there may be provided a shutter 131 and valves (open-close members) 117 and 127 each for turning on/off the supply of vapor deposition particles from the vapor deposition particle generating sections. This makes it possible to instantaneously change the vapor deposition rate.

Specifically, assuming that vapor deposition rates attributed to supply sources are RA and Ra, the total vapor deposition rate can be changed to the following rates by the valves 117 and 127: (1) RA, (2) RA+Ra, and (3) Ra. Note however that, before the change, the vapor deposition rates of the vapor deposition particle generating sections need to be stabilized. In a case where, as in a conventional technique, there is only one vapor deposition particle generating section, it is not possible to instantaneously change the vapor deposition rate.

Furthermore, as shown by a dash-dot-dot line in FIG. 1, the shutter 131 is provided between the vapor deposition mask 300 and the nozzle section 170, so as to control whether or not the vapor deposition particles injected from the nozzle section 170 are allowed to reach the mask 300. The shutter 131 is used to determine whether or not to inject the vapor deposition particles toward the film formation substrate 200.

The shutter 131 prevents the vapor deposition particles from being injected in the vacuum chamber 500 when a vapor deposition rate is to be stabilized or vapor deposition is not required.

The shutter 131 is provided between, for example, the vapor deposition mask 300 and the nozzle section 170 so that the shutter 131 can be freely inserted and removed by a shutter operating unit (not illustrated). This arrangement blocks vapor deposition particles to prevent the vapor deposition particles from reaching the film formation substrate 200 while, for example, an alignment between the film formation substrate 200 and the vapor deposition mask 300 is carried out.

The shutter 131 covers the injection holes 171 for the vapor deposition particles (vapor deposition material) in the nozzle section 170 while a film is not being formed on the vapor deposition target substrate 200.

The vapor deposition particle generating section a has a small capacity for a vapor deposition material. However, since the vapor deposition particle generating section a less contributes to the total vapor deposition rate (i.e., since the flow rate of vapor deposition particles released from the vapor deposition particle generating section a accounts for a smaller proportion), the vapor deposition particle generating section a is capable of being used for vapor deposition for a period of time as long as the vapor deposition particle generating section A.

In a case where only a single vapor deposition particle generating section is provided like a conventional technique, it is necessary to increase the temperature of a crucible to a higher temperature in order to increase the vapor deposition rate. This generates more heat, which causes more damage to the vapor deposition material. In this regard, according to the arrangement of the vapor deposition device in accordance with the present embodiment, it is not necessary to increase the temperature of a crucible so much. This makes it possible to suppress material deterioration.

<Effect of Reducing the Time Required for the Vapor Deposition Rate to Become Stable>

The following describes, with reference to (b) of FIG. 9, how the time required for the vapor deposition rate to become stable is reduced.

Note here that, since the vapor deposition rate of the vapor deposition particle generating section A increases slowly, a vapor deposition material is uselessly released until the vapor deposition rate becomes stable. In order to reduce such a loss, the vapor deposition particle generating device a is used in combination with the vapor deposition particle generating section A. The vapor deposition rate of the vapor deposition particle generating section a increases quickly. Therefore, first, a flow of vapor deposition particles released from the vapor deposition particle generating section a is used mainly so that a desired predetermined vapor deposition rate is quickly reached.

After that, as the flow rate of vapor deposition particles supplied from the vapor deposition particle generating section A increases, the flow rate of the vapor deposition particles supplied from the vapor deposition particle generating section a is reduced. Note here that these flow rates are controlled so that the total vapor deposition rate is kept constant. As described earlier, such flow rates are controlled precisely by use of the heaters and the values measured by the individual rate monitors and the total rate monitor.

The above method makes it possible to quickly stabilize the vapor deposition rate, and thus to improve material use efficiency. Furthermore, since the vapor deposition particle generating section a is used only until the vapor deposition rate attributed to the vapor deposition particle generating section A reaches a predetermined value, the vapor deposition particle generating section a is capable of being used for vapor deposition for a long period of time despite its small capacity for a vapor deposition material.

The above method can be used also to reduce the vapor deposition rate of the vapor deposition particle generating section A. Specifically, in a case where the operation of the vapor deposition particle generating section A needs to be stopped for the purpose of adding a material etc., heating is stopped whereby the flow rate of the vapor deposition particles supplied from the vapor deposition particle generating section A gradually decreases. Here, since the decreased flow rate is covered by the flow rate of vapor deposition particles from the vapor deposition particle generating section a, it is possible to keep the desired vapor deposition rate even while the vapor deposition particle generating section A undergoes a transition to a stopped state. At the same time, it is possible to make use of the flow of vapor deposition particles having a decreasing vapor deposition rate, which are supplied from the vapor deposition particle generating section A. This makes it possible to improve material use efficiency.

Moreover, there is another effect. That is, even in a case where the flow rate of vapor deposition particles supplied from the vapor deposition particle generating section A becomes unstable due to disturbance or a change in the amount of vapor remaining deposition materials etc., it is possible to suppress instability of the vapor deposition rate by using the flow of vapor deposition particles from the vapor deposition particle generating section a.

Note that, although the present embodiment describes an example in which the vapor deposition particle injection device 501 includes one (1) vapor deposition particle generating section 120 which has a small capacity for a vapor deposition material, the present invention is not limited to such an arrangement. A plurality of such vapor deposition particle generating sections can be provided.

Further, although the present embodiment describes an example in which the vapor deposition particle generating sections 110 and 120 of the vapor deposition particle injection device 501 are provided inside the vacuum chamber 500, the present invention is not limited to such an arrangement. The vapor deposition particle generating sections 110 and 120 can be provided outside the vacuum chamber 500. For example, the following arrangement is also available: the vapor deposition particle generating sections 110 and 120 are taken out of the vacuum chamber and placed in a load lock chamber which is separately provided, and the load lock chamber is connected to the vacuum chamber 500 via a guiding pipe for guiding vapor deposition materials in the form of vapor to the vacuum chamber 500. Since the load lock chamber can be evacuated and ventilated independently of the vacuum chamber 500 (film formation chamber), it is possible to add a material without causing the vacuum chamber 500 to be open to air. Further, in a case where the load lock chamber is smaller than the vacuum chamber 500, it is also possible to quickly reduce the pressure inside the load lock chamber to a desired pressure.

As has been described, according to the vapor deposition particle injection device in accordance with the present embodiment, a vapor deposition material use efficiency is improved by reducing the time from when a vapor deposition starts to when a desired vapor deposition rate is reached, by using the vapor deposition particle generating sections having different capacities for a material. The following Embodiment 2 deals with an arrangement in which a vapor deposition material use efficiency is improved in another way.

### Embodiment 2

The following will discuss another embodiment of the present invention. Note that, for convenience of description, members having functions identical to those of the respective members described in Embodiment 1 are given respective identical reference numerals, and descriptions of those members are omitted here.

<Overall Configuration of Vapor Deposition Device>

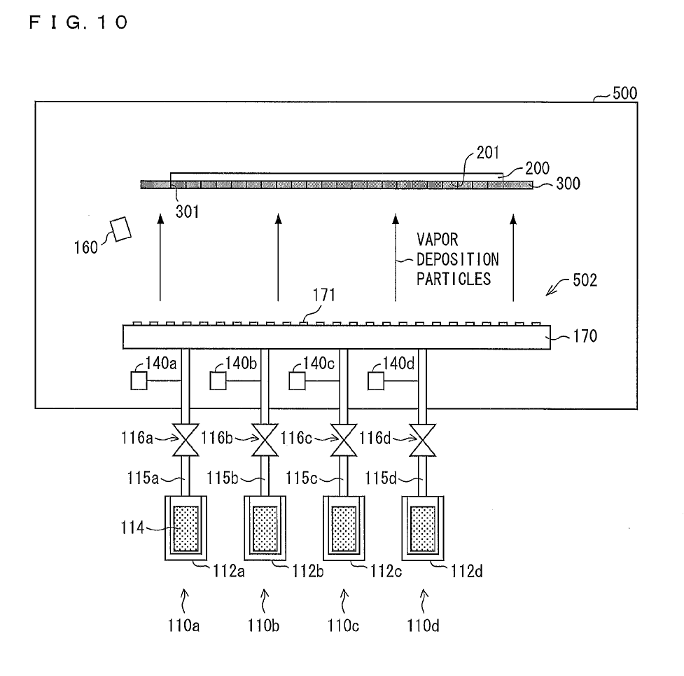

FIG. 10 schematically illustrates an overall configuration of a vapor deposition device.

As illustrated in FIG. 10, the vapor deposition device includes, as a vapor deposition source, a vapor deposition particle injection device 502 including (i) a nozzle section (vapor deposition particle injecting section) 170 having a plurality of injection holes 171, which is provided inside a vacuum chamber 500 and (ii) four vapor deposition particle generating sections 110a to 110d. Further, in the upper portion of the vacuum chamber 500, a vapor deposition mask 300 and a film formation substrate 200 are arranged so as to face toward the nozzle section 170 of the vapor deposition particle injection device 502.

According to the vapor deposition device thus arranged, vapor deposition materials 114 contained in the four vapor deposition particle generating sections 110a to 110d, respectively, are heated by heaters 112a to 112d which are provided to the four vapor deposition particle generating sections 110a to 110d, respectively, whereby vapor deposition particles in the form of vapor are generated.

The vapor deposition particle generating sections 110a to 110d are configured such that they can be heated independently of each other and their vapor deposition rates can be controlled independently of each other. The four vapor deposition particle generating sections 110a to 110d are sequentially heated. When one vapor deposition particle generating section has run out of the vapor deposition material 114, another vapor deposition particle generating section starts being heated.

Vapor deposition particles generated by the vapor deposition particle generating sections 110a to 110d are guided to the nozzle section 170 via pipes 115a to 115d connected to the vapor deposition particle generating section 110a to 110d, respectively. After that, the vapor deposition particles are injected towards the film formation substrate 200 from the injection holes 171 which are arranged in a line.

Note that, also in the present embodiment, it is possible to form a pattern of a vapor deposition film by depositing the vapor deposition particles on a surface of the film formation substrate 200 through the vapor deposition mask 300.

Also in the present embodiment, a scan vapor deposition is carried out in the following manner. While the vapor deposition particle injection device 502 is fixed and the film formation substrate 200 and the vapor deposition mask 300 are closely fixed to each other, vapor deposition is carried out by moving (scanning) the film formation substrate 200 in a direction perpendicular to a surface of a sheet on which FIG. 10 is illustrated (i.e., in a direction perpendicular to a direction along which the injection holes 171 are arranged). Alternatively, a scan vapor deposition is carried out, while the film formation substrate 200 is fixed, by moving the vapor deposition particle injection device 502 in the direction perpendicular to the direction along which the injection holes 171 are arranged.

As is the case with Embodiment 1, the vapor deposition mask 300 has openings 301 of desired shapes in desired positions. Only vapor deposition particles which have passed through the openings reach the film formation substrate 200 and form a vapor deposition film. In a case where a pattern is formed for each pixel, a mask (fine mask) having openings corresponding to respective pixels is used. In a case where vapor deposition particles are to be deposited in an entire display region, a mask (open mask) having an opening which corresponds to the entire display region is used. An example of a film to be formed for each pixel is a luminescent layer. An example of a film to be formed in the entire display region is a hole transfer layer.

The vapor deposition particle generating sections 110a to 110d are provided with the pipes 115a to 115d, respectively, for leading out generated vapor deposition particles. The pipes 115a to 115d are directly connected to the nozzle section 170. This causes the vapor deposition particles generated by the vapor deposition particle generating sections 110a to 110d to be guided to the nozzle section 170 via the pipes 115a to 115d.

The pipes 115a to 115d are provided with individual rate monitors 140a to 140d for monitoring the flow rates of vapor deposition particles (the amounts of vapor deposition particles) from the vapor deposition particle generating sections 110a to 110d, respectively.

The individual rate monitors 140a to 140d are configured to measure the amounts of vapor deposition particles (the flow rates of vapor deposition particles) passing through the pipes 115a to 115d, respectively.

Further, the vapor deposition particle injection device 502 includes a total rate monitor 160 for monitoring a total flow rate of vapor deposition particles (the total amount of vapor deposition particles).

The total rate monitor 160 measures the amount (the flow rate) of vapor deposition particles injected from the injection holes 171 and supplied to the film formation substrate 200.

That is, the flow rates of vapor deposition particles supplied from the vapor deposition particle generating sections 110a to 110d are measured in real time by the individual rate monitors 140a to 140d, respectively. Meanwhile, the total flow rate of vapor deposition particles (corresponding to the amount of vapor deposition particles that form a film on a substrate) is also measured by the total rate monitor 160. According to the values measured by these rate monitors, heat quantities for the vapor deposition particle generating sections 110a to 110d are controlled independently of each other. This control is described later in detail.

Further, the pipes 115a to 115d are provided with valves (open-close members) 116a to 116d.

The valves 116a to 116d open or close the pipes 115a to 115d, respectively, thereby allowing the vapor deposition particles to flow within the pipes 115a to 115d or stopping the supply of the vapor deposition particles. Such a control is described later.

Further, the vapor deposition particle generating sections 110a to 110d include the heaters 112a to 112d, respectively, for heating vapor deposition materials contained in the vapor deposition particle generating sections 110a to 110d.

As is clear from above, according to the present embodiment, the supply of vapor deposition particles to the nozzle section 170 from the vapor deposition particle generating sections 110a to 110d can be controlled not only by controlling the operation of the heaters 112a to 112d (by turning ON or turning OFF electric currents) but also by opening and closing the valves 116a to 116d.

Specifically, in a case where the supply of vapor deposition particles is controlled by controlling (by turning ON or turning OFF electric currents) the heaters 112a to 112d, it is not possible to immediately stop the generation of vapor deposition particles. However, it is possible to quickly stop the generation of the vapor deposition particles only by controlling the opening and closing of the valves 116a to 116d, namely, simply by closing open valves.

As such, the supply of vapor deposition particles to the nozzle section 170 from each of the vapor deposition particle generating sections 110a to 110d can be controlled individually, by controlling the operation of each of the heaters 112a to 112d independently and controlling the opening and closing of each of the valves 116a to 116d independently.

By individually controlling the supply of vapor deposition particles from each of the vapor deposition particle generating sections 110a to 110d to the nozzle section 170 like above, it is possible to sequentially use the vapor deposition particle generating sections 110a to 110d.

For example, assume that a vapor-deposited film is being formed only with the use of the vapor deposition particle generating section 110a. In this case, when the vapor deposition material in the vapor deposition particle generating section 110a is running short and replacement becomes necessary, the vapor deposition particle generating section 110b is started to form a vapor-deposited film. By changing a vapor deposition particle generating section to a next vapor deposition particle generating section when the vapor deposition material is running short and replacement becomes necessary like above, it is possible to continuously form a vapor-deposited film.

In general, as described also in Embodiment 1, it takes a relatively long time from when the operation of a vapor deposition particle generating section is started (an electric current is allowed to pass through a heater) to when a predetermined vapor deposition rate is reached. Therefore, in the case of sequentially using the vapor deposition particle generating sections as described above, the vapor deposition rate may become unstable depending on when one vapor deposition particle generating section is switched to another vapor deposition particle generating section. By adjusting when to switch between vapor deposition particle generating sections, it is possible to keep a stable vapor deposition rate even in a case where a plurality of vapor deposition particle generating sections are used sequentially.

The following description discusses a control block diagram and a flow of a control process, each of which is for carrying out vapor deposition control in the vapor deposition particle injection device 502 in accordance with the present embodiment.

<Block Diagram for Vapor Deposition Control>

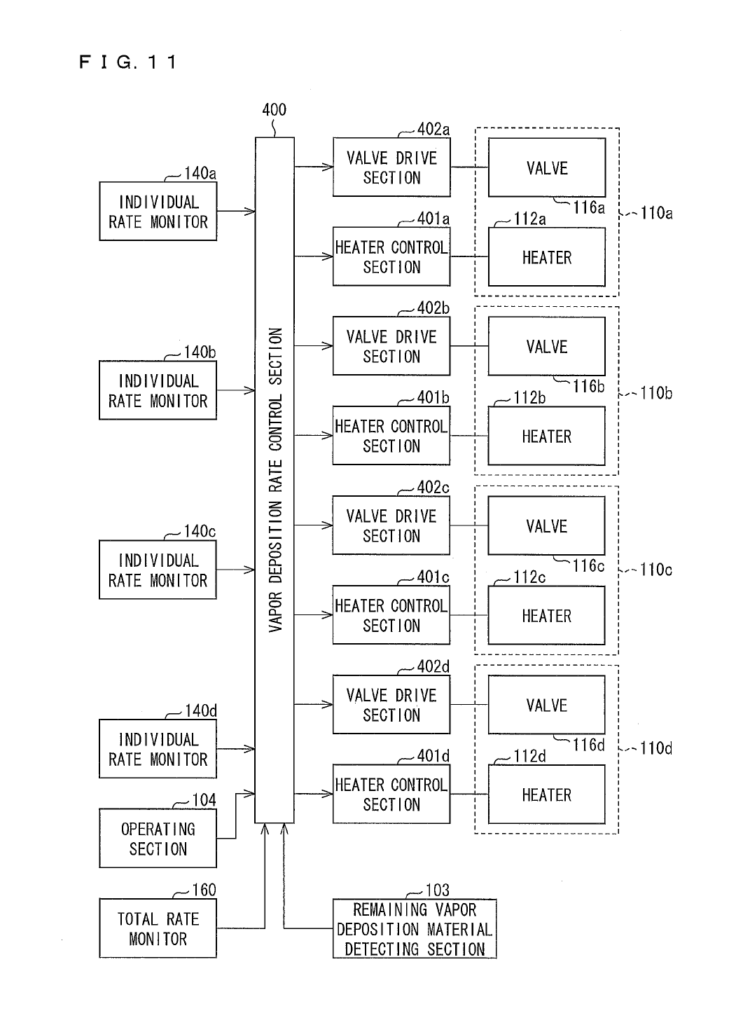

FIG. 11 is a block diagram which illustrates how vapor deposition is controlled in the vapor deposition particle injection device 502.

The vapor deposition particle injection device 502 includes, as shown in FIG. 11, a control section for controlling vapor deposition, which is constituted by (i) a vapor deposition rate control section (drive control section) 400 for carrying out main control, (ii) heater control sections 401a to 401d for controlling supply of drive currents to the heaters 112a to 112d of the vapor deposition particle generating sections 110a to 110d, and (iii) valve drive sections 402a to 402d for opening and closing the valves 116a to 116d of the vapor deposition particle generating sections 110a to 110d.

The vapor deposition rate control section 400 is configured to: receive (i) data (monitor result) from the individual rate monitors 140a to 140d which monitor the vapor deposition rates of the vapor deposition particle generating sections 110a to 110d, (ii) data (monitor result) from the total rate monitor 160 which monitors the vapor deposition rate of the vapor deposition device as a whole, (iii) data (detection result) from a remaining vapor deposition material detecting section 103 which detects the amounts of vapor deposition materials remaining in the vapor deposition particle generating sections 110a to 110d, and (iv) data (set vapor deposition rate) inputted via an operating section 104; and output control instruction signals to the heater control sections 401a to 401d and the valve drive sections 402a to 402d in accordance with the data thus received.

The data (monitor result) received from the individual rate monitors 140a to 140d are, for example, values obtained by measuring the flow rates of vapor deposition particles from the vapor deposition particle generating sections 110. The vapor deposition rate control section 400 compares the data from the individual rate monitors 140 with the data from the operating section 104 (set vapor deposition rate), and determines whether or not each of the vapor deposition rates of the vapor deposition particle generating sections 110 has reached a desired vapor deposition rate (set vapor deposition rate).

The data (monitor result) received from the individual rate monitor 160 is a value obtained by measuring the flow rate of vapor deposition particles in the entire vapor deposition particle injection device 502. The vapor deposition rate control section 400 compares the value with the data from the operating section 104 (set vapor deposition rate), and determines whether or not the value has reached the desired vapor deposition rate (set vapor deposition rate).

Furthermore, the vapor deposition rate control section 400 determines, according to the detection result received from the remaining vapor deposition material detecting section 103, whether or not to stop the operations (generation of vapor deposition particles) of the vapor deposition particle generating sections 110a to 110d.

Next, the description below deals with a flow of a vapor deposition control process in the vapor deposition rate control section 400.

<Vapor Deposition Control Process Flowchart>

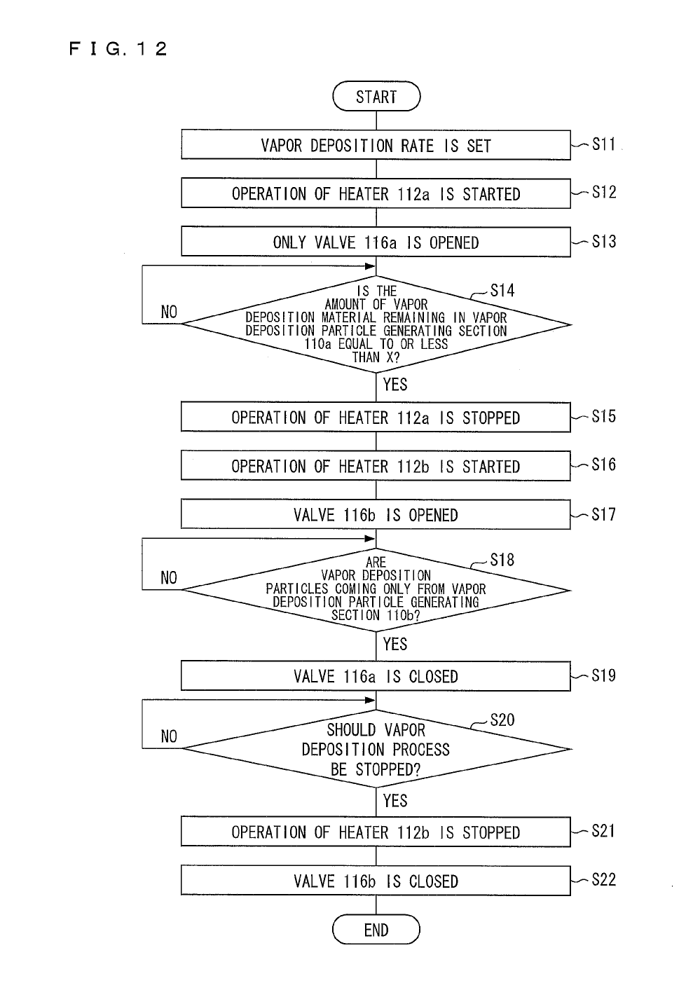

FIG. 12 is a flowchart indicating successive steps of a vapor deposition control process carried out in the vapor deposition particle injection device 502.

First, a vapor deposition rate of the vapor deposition particle injection device 502 is set (S11). Note here that the vapor deposition rate control section 400 receives information indicative of a desired vapor deposition rate, and sets the vapor deposition rate in accordance with the information. Note that, at this point, the valves 116a to 116d are all closed.

Next, the operation of the heater 112a is started (S12). Note here that the vapor deposition rate control section 400 sends, in accordance with the information indicative of the desired vapor deposition rate received from the operating section 104, a drive signal for driving the heater 112a of the vapor deposition particle generating section 110a to the heater control section 401a. The heater control section 401a, which received the drive signal, carries out a control such that a drive current is supplied to the heater 112a, thereby starting the operation of the heater 112a.

Next, only the valve 116a is opened (S13). Note here that the vapor deposition rate control section 400 sends, in accordance with the information indicative of the desired vapor deposition rate received from the operating section 104, a drive signal to the valve driving section 402a, which drive signal is to open the valve 116a of the vapor deposition particle generating section 110a. The valve drive section 402a, which received the drive signal, drives the valve 116a so as to open the valve 116a.

Next, it is determined whether or not the amount of a vapor deposition material remaining in the vapor deposition particle generating section 110a is not more than a predetermined amount X (S14). Note here that the vapor deposition rate control section 100 checks the detection result received from the remaining vapor deposition material detecting section 103, and determines whether or not the amount of the vapor deposition material remaining in the vapor deposition particle generating section 110a is not more than the predetermined amount X. That is, in S14, the amount of a vapor deposition material remaining in the vapor deposition particle generating section 110a is monitored.

In a case where it is determined that the amount of the vapor deposition material remaining in the vapor deposition particle generating section 110a is not more than the predetermined amount X in S14, the process proceeds to S15, and the operation of the heater 112a of the vapor deposition particle generating section 110a is stopped.

Note here that the predetermined amount X is such an amount that a vapor deposition cannot be stably carried out, and also is an amount according to which to determine whether or not to stop the operation of the vapor deposition particle generating section 110. The predetermined amount X is set in consideration of the time from when the operation of a next vapor deposition particle generating section (the vapor deposition particle generating section 110b) is started to when a predetermined vapor deposition rate is reached.

That is, the predetermined amount X is a reference according to which to determine when to stop the operation of the vapor deposition particle generating section 110, and is also a reference according to which to determine when to start the operation of the next vapor deposition particle generating section 110.

That is, it is only necessary to set the predetermined amount X such that the desired vapor deposition rate is kept constant even while one vapor deposition particle generating section 110 is switched to another vapor deposition particle generating section 110. Therefore, it is only necessary to set the predetermined amount X as appropriate in accordance with, for example, (i) the capacity, for a vapor deposition material, of each of the vapor deposition particle generating sections 110 and (ii) the type of the vapor deposition material.

Next, the operation of the heater 112a of the vapor deposition particle generating section 110a is stopped in S15. At the same time, the operation of the heater 112b of the vapor deposition particle generating section 110b is started (S16) and the valve 116b of the vapor deposition particle generating section 110b is opened (S17). At this time, heating of the vapor deposition particle generating section 110a is stopped; however, since the valve 116a is still open, the vapor deposition particles keep being supplied to the nozzle section 170 from the vapor deposition particle generating section 110a. That is, at this point, the vapor deposition particles are supplied to the nozzle section 170 from both the vapor deposition particle generating section 110a and the vapor deposition particle generating section 110b.

Next, it is determined whether or not all the vapor deposition particles are supplied from the vapor deposition particle generating section 110b (S18). Note here that the vapor deposition rate control section 400 monitors, with reference to the monitor result supplied from the individual rate monitor 140a which monitors the flow rate of vapor deposition particles supplied from the vapor deposition particle generating section 110a, whether or not the generation of the vapor deposition particles in the vapor deposition particle generating section 110a is stopped.

If it turns out that no vapor deposition particles are generated in the vapor deposition particle generating section 110a, the vapor deposition rate control section 400 determines that all the vapor deposition particles are supplied from the vapor deposition particle generating section 110b, and closes the valve 116a of the vapor deposition particle generating section 110a (S19).

Next, it is determined whether or not the vapor deposition process is to be stopped (S20). Note here that the vapor deposition rate control section 400 waits until it receives a vapor deposition process stop signal such as that from the operating section 104. Upon receiving the vapor deposition process stop signal, the vapor deposition rate control section 400 controls the heater control section 401b and the valve drive 402b so that (i) the operation of the heater 112b of the vapor deposition particle generating section 110b is stopped (S21) and (i) the valve 116b of the vapor deposition particle generating section 110b is closed (S22).

By carrying out the foregoing process also with respect to the vapor deposition particle generating sections 110c and 110d, the vapor deposition process is carried out by sequentially using the vapor deposition particle generating sections 110a to 110d.

<Regarding Operation and Effect>

According to the present embodiment, the vapor deposition rate control section 400, which serves as a drive control section, drives the vapor deposition particle generating sections 110a to 110d sequentially while keeping the vapor deposition rate of the vapor deposition particle injection device 502 constant. Therefore, it is possible to also use, for film formation, vapor deposition particles having a decreasing or increasing flow rate which are generated while one of the vapor deposition particle generating sections 110a to 110d is switched to another one of the vapor deposition particle generating sections 110a to 110d. This makes it possible to improve use efficiency of a vapor deposition material.

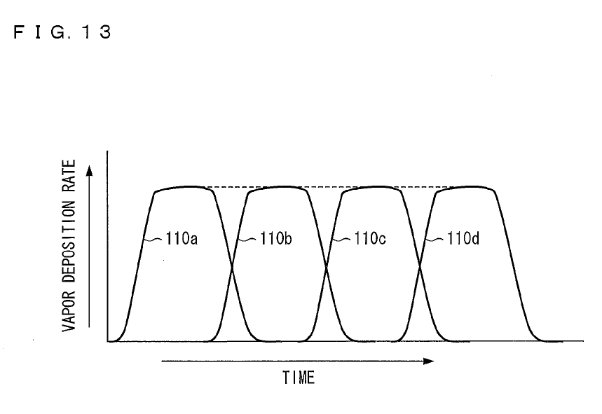

FIG. 13 is a graph illustrating a relationship between time and vapor deposition rates of the vapor deposition particle generating sections 110a to 110d in the vapor deposition device of the present embodiment. Note that periods during which the vapor deposition rates are stable, which periods are shown in the graph, are illustrated so as to be shorter than actual periods.

When the vapor deposition particle generating sections 110a to 110d are heated, the vapor deposition rates of the vapor deposition particle generating sections 110a to 110d increase as shown in FIG. 13. Each of the vapor deposition particle generating sections 110a to 110d has the same structure as that of the vapor deposition particle generating section 110 of Embodiment 1. That is, although it is good that each of the vapor deposition particle generating sections 110a to 110d is capable of containing a large amount of vapor deposition material, it takes a long time for the vapor deposition rate to become stable.

The flow rates of vapor deposition particles from the vapor deposition particle generating sections 110a to 110d are precisely controlled according to values measured by the individual rate monitors 140a to 140d and the total rate monitor 160 (see FIG. 10). Note however that, if it is clear in advance how the temperatures of the vapor deposition particle generating sections 110a to 110d are related to the flow rates of vapor deposition particles, the control can be carried out with the use of only the total rate monitor 160.

Furthermore, it is possible to control, as appropriate, when to switch one of the vapor deposition particle generating sections 110a to 110d to another one of the vapor deposition particle generating sections 110a to 110d.

According to the vapor deposition device in accordance with the present embodiment, it is possible to also utilize, for film formation, a flow of vapor deposition particles having a decreasing or increasing vapor deposition rate, by sequentially using the vapor deposition particle generating sections 110a to 110d while keeping the vapor deposition rate constant. This improves material use efficiency.

The present embodiment has described an example in which four vapor deposition particle generating sections are employed. Note, however, that this does not imply any limitation. It is only necessary that at least two vapor deposition particle generating sections be provided. For example, provided that the vapor deposition particle generating section 110a can be refilled with material and preparation for heating the vapor deposition particle generating section 110a can be completed within a period of time during which the vapor deposition particle generating section 110b is in operation, the vapor deposition particle generating sections 110c to 110d are not essential.

Note however that, in order to reduce the frequency of material refill and in order not to stop the vapor deposition process even when a vapor deposition particle generating section suffers a problem, it is preferable to provide three or more vapor deposition particle generating sections.

The present Embodiment 2 described an example in which a plurality of vapor deposition particle generating sections of the same type are employed. The following Embodiment 3 deals with an example in which at least one of the plurality of vapor deposition particle generating sections is a vapor deposition particle generating section, as described earlier in Embodiment 1, that has a smaller capacity for a vapor deposition material than other vapor deposition particle generating sections.

### Embodiment 3

The following will discuss a further embodiment of the present invention.

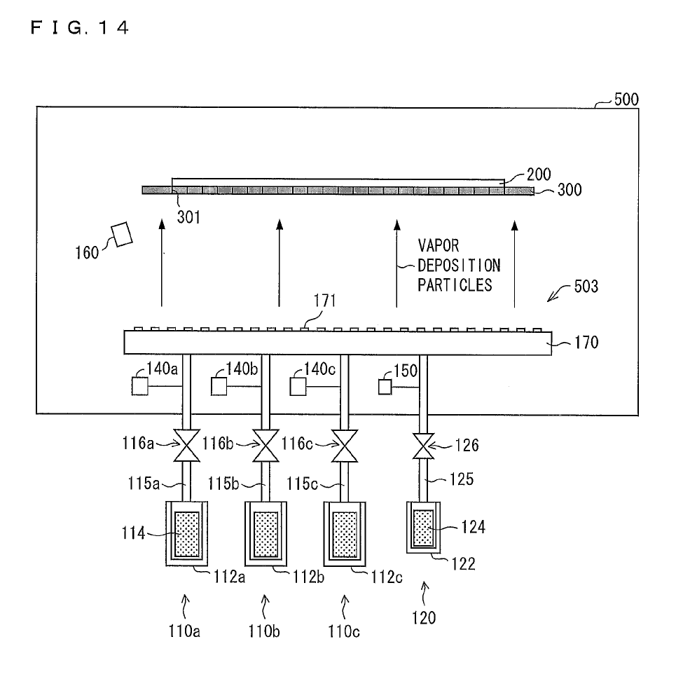

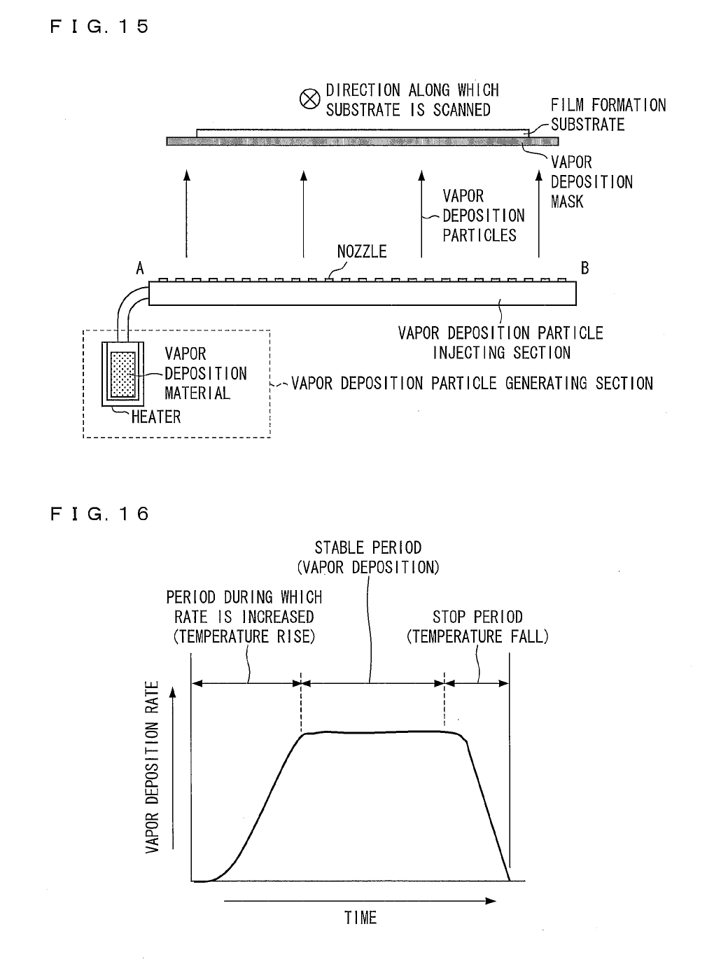

A configuration according to the present embodiment is the same as that of the vapor deposition particle injection device 502 shown in FIG. 10 of Embodiment 2, except that, as shown in FIG. 14, the configuration according to the present embodiment includes a vapor deposition particle injection device 503 including the vapor deposition particle generating section 120 shown in FIG. 1 of Embodiment 1 in place of the vapor deposition particle generating section 110d shown in FIG. 10.

The vapor deposition particle generating section 120 is designed to be capable of containing a smaller amount of vapor deposition material 124, as compared to the vapor deposition materials 114 of other vapor deposition particle generating sections 110a to 110c.

In the present embodiment, the operation of the vapor deposition particle generating section 120 is started first, and, after that, the operations of the other vapor deposition particle generating sections 110a to 110c are sequentially started at predetermined times.

Note that a vapor deposition control block diagram and a vapor deposition control process flowchart are the same as those of Embodiment 2, and therefore detailed descriptions of them are omitted here.

According to the vapor deposition particle injection device 503 of the present embodiment, the vapor deposition particle generating section 120, whose operation is started first, has a smaller capacity for the vapor deposition material 124 than the vapor deposition particle generating sections 110a to 110c. Therefore, less time is required for a contained vapor deposition material to be thoroughly heated, as compared to the vapor deposition particle generating sections 110a to 110c.

This makes it possible, in the vapor deposition particle injection device 503 including a plurality of vapor deposition particle generating sections, to reduce the time from when vapor deposition starts to when a set vapor deposition rate is reached.

Furthermore, as described in Embodiment 2, it is also possible to utilize, for film formation, a flow of vapor deposition particles having a decreasing or increasing vapor deposition rate by sequentially using the vapor deposition particle generating sections 110a to 110d while keeping the vapor deposition rate constant. This makes it possible to improve material use efficiency.

Moreover, even if a target vapor deposition rate is changed in the middle of a vapor deposition process, it is possible to quickly change the vapor deposition rate by again starting the operation of the vapor deposition particle generating section 120 first.

Note that, as is the case with Embodiment 1, the operation of one of the vapor deposition particle generating sections 110a to 110c can be started at the same time as start of the operation of the vapor deposition particle generating section 120.

The following will discuss a modification example of the present invention.

<Down Deposition>

Embodiments 1 to 3 have described an example in which (i) the vapor deposition particle injection device 501, 502 or 503 is provided below the film formation substrate 200 and (ii) the vapor deposition particle injection device 501, 502 or 503 injects vapor deposition particles upward so that the vapor deposition particles pass through the opening 301 in the vapor deposition mask 300 and are deposited from below (such a vapor deposition is referred to as up deposition). Note, however, that the present invention is not limited to such an arrangement.

For example, the following arrangement is also available: (i) the vapor deposition particle injection device 501, 502 or 503 is provided above the film formation substrate 200 and (ii) vapor deposition particles injected downward and passed through the opening 301 in the vapor deposition mask 300 are deposited from top onto the film formation substrate 200 (such a vapor deposition is referred to as down deposition).

In a case where vapor deposition is carried out by down deposition in this way, a high-definition pattern can be formed with a high accuracy all over the film formation substrate 200 even without a substrate supporting member (e.g., electrostatic chuck) for supporting the film formation substrate 200, which is to suppress bending of the film formation substrate 200 by self weight.

<Side Deposition>

Alternatively, the vapor deposition particle injection device 501, 502 or 503 may be configured to include, for example, a mechanism that injects the vapor deposition particles in a transverse direction. Then, the vapor deposition particle injection device 501, 502 or 503 may carry out vapor deposition (side deposition) of the vapor deposition particles in the transverse direction through the vapor deposition mask 300 onto the film formation substrate 200 in a state in which the film formation surface 201 of the film formation substrate 200 stands upright so as to face the vapor deposition particle injection device 30.

### Other Modification Examples

The shapes (shapes as viewed from above) of the injection holes 171 in the nozzle section 170 are not particularly limited. The injection holes 171 may have various shapes such as a circle and a rectangle.

Further, the injection holes 171 in the nozzle section 170 can be arranged one-dimensionally (namely, a line) or arranged two-dimensionally (namely, a plane).

In the case of a vapor deposition device in which the film formation substrate 200 and the vapor deposition mask 300 are moved along one direction relative to the nozzle section 170, a larger number of injection holes can cover a film formation substrate 200 having a larger area.

Embodiment 1 has described an example case in which (i) the organic EL display device 1 includes a TFT substrate 10 and (ii) an organic layer is formed on the TFT substrate 10. The present invention is, however, not limited to such an arrangement. The present invention may alternatively be arranged such that (i) the organic EL display device 1 includes not a TFT substrate 10 but, as a substrate on which an organic layer is to be formed, a passive substrate including no TFT, or that (ii) the film formation substrate 200 is such a passive substrate.

Embodiment 1 has described an example case of, as described above, forming an organic layer on a TFT substrate 10. The present invention is, however, not limited to such an arrangement. The present invention is suitably applicable to a case of depositing the second electrode 26 instead of an organic layer. The present invention is also applicable to (i) a case where a sealing film is used to seal the organic EL elements 20 and (ii) a case of depositing the sealing film. The vapor deposition particle injection devices 501 to 503 and the vapor deposition device are applicable, for example, not only to the organic EL display device 1 but also to production of a functional device such as an organic thin-film transistor.

Although the foregoing Embodiments 1 to 3 deal with the vapor deposition particle injection devices 501 to 503 which are line-type vapor deposition sources, this does not imply any limitation. The vapor deposition particle injection devices 501 to 503 may be each a credible-type vapor deposition source or a planar vapor deposition source.

Further, the effects brought about by the present invention do not depend on the shape of an injection hole(s) in the nozzle section. Specifically, a large number of injection holes may be arranged or one single long injection hole may be provided.

The present invention is particularly effective when a material to be used takes time to have a stable vapor deposition rate. For example, for a material (e.g., organic material) that is prone to deterioration when subjected to a rapid temperature rise, the present invention makes it possible to improve process tact (throughput) because the vapor deposition rate is reached within a short period of time. Furthermore, the present invention is particularly effective when an expensive vapor deposition material is used such as a material for an organic layer of an organic EL element. The present invention makes it possible, by reducing the time required for the vapor deposition rate to become stable and using a plurality of vapor deposition sources in combination, to cause the material to contribute to vapor deposition even while the temperature increases or decreases, and thus possible to use the vapor deposition material effectively.

The vapor deposition particle injection device of the present invention is applicable not only to production of an organic EL display device but also to production of other things provided that the production includes forming a film by vapor deposition.

Furthermore, the present invention makes it possible, by using the vapor deposition particle injection device 501, 502 or 503 of Embodiment 1, 2 or 3 as a vapor deposition source in the vapor deposition device for use in production of the organic EL elements 20, to quickly carry out a change of the vapor deposition rate which is necessitated by switching between production steps. This makes it possible to avoid a waste of vapor deposition particles which are otherwise wasted while the vapor deposition rate is changed, and thus possible to improve material use efficiency.

This makes it possible to reduce costs for production of organic EL elements, and thus possible to produce an organic EL display device at low cost.

In order to cause a target vapor deposition rate of a vapor deposition particle source to be reached quicker than a target vapor deposition rate of another vapor deposition particle source, it is only necessary to cause the vapor deposition source to have a smaller capacity for the vapor deposition material than the another vapor deposition particle source, in the following manner.

The vapor deposition particle injection device in accordance with the present invention is configured such that at least one of the plurality of vapor deposition particle sources has a smaller capacity for the vapor deposition material than the other(s) of the plurality of vapor deposition particle sources.

In order to attain the above object, a vapor deposition particle injection device in accordance with the present invention includes: a plurality of vapor deposition particle sources for generating vapor deposition particles in the form of vapor by heating a vapor deposition material; and an injection container which (i) is connected to the plurality of vapor deposition particle sources and (ii) has an injection hole from which the vapor deposition particles generated by the plurality of vapor deposition particle sources are injected outward, at least one of the plurality of vapor deposition particle sources having a smaller capacity for the vapor deposition material than the other(s) of the plurality of vapor deposition particle sources.

In general, the time from when a vapor deposition material is heated so as to become vapor deposition particles to when the speed (vapor deposition rate) of the vapor deposition particles reaches a speed (vapor deposition rate) at which the vapor deposition particles stably form a vapor-deposited film on a film formation subject (film formation substrate) increases in proportion to the capacity for the vapor deposition material. This is because, if the capacity for the vapor deposition material is large, it takes a long time for the vapor deposition material to be thoroughly heated, and thus more time is required for the vapor deposition particles to be stably generated from the vapor deposition material.

In view of the circumstances, according to the configuration, at least one of the vapor deposition particle sources has a smaller capacity for the vapor deposition material than the other(s) of the vapor deposition particle sources. This causes the vapor deposition material in the at least one of the vapor deposition particle sources to be thoroughly heated more quickly than those in the other(s) of the vapor deposition particle sources.

This causes a target vapor deposition rate of the at least one of the vapor deposition particle sources to be reached more quickly than a target vapor deposition rate of the other(s) of the vapor deposition particle sources, and thus makes it possible, when a vapor deposition rate is changed to a new vapor deposition rate, to reduce the time required for the new vapor deposition rate to be reached, as compared with the case where all the vapor deposition particle sources have the same capacity for the vapor deposition material.

Accordingly, it is possible to reduce the time from when vapor deposition is started to when a set vapor deposition rate is reached.

Since it is possible to reduce the time from when the vapor deposition is started to when the set vapor deposition rate is reached like above, it is possible, even when an instruction is given to change the vapor deposition rate in the middle of vapor deposition, to reduce the time required for a new vapor deposition rate to be reached. That is, it is possible to quickly change the vapor deposition rate.

The vapor deposition particle injection device in accordance with the present invention preferably further includes: a vapor deposition rate control section for controlling a vapor deposition rate of each of the plurality of vapor deposition particle sources, the vapor deposition rate being a flow rate of the vapor deposition particles which flow from the each of the plurality of vapor deposition particle sources to the injection container, the vapor deposition rate control section concurrently controlling vapor deposition rates of at least two of the plurality of vapor deposition particle sources, one of the at least two of the plurality of vapor deposition particle sources being the at least one of the plurality of vapor deposition particle sources which has a smaller capacity for the vapor deposition material than the other(s) of the plurality of vapor deposition particle sources.

According to the configuration, the operations of the vapor deposition rates of at least two of the plurality of vapor deposition particle sources, one of which has a smaller capacity for the vapor deposition material than the other(s) of the plurality of vapor deposition particle sources, are started at the same time. Therefore, the vapor deposition rate of a first vapor deposition particle source that has a smaller capacity for the vapor deposition material becomes stable before that of a second vapor deposition particle source that has a larger capacity for the vapor deposition material becomes stable. This makes it possible to use, for vapor deposition, vapor deposition particles generated while the vapor deposition rate of the second vapor deposition particle source is not stable, because the first vapor deposition particle source, whose vapor deposition rate has become stable, makes up for a shortage of vapor deposition particles.

As such, the vapor deposition particles generated while the vapor deposition rate of the second vapor deposition particle source is not stable are not wasted, but are used effectively. This makes it possible to more effectively use the vapor deposition material.

The vapor deposition particle injection device in accordance with the present invention is preferably configured such that the at least two, of the plurality of vapor deposition particle sources, whose vapor deposition rates are concurrently controlled by the vapor deposition rate control section, contain the same vapor deposition material.

Since the vapor deposition particle sources whose vapor deposition rates are controlled together contain the same type of vapor deposition material, it is possible to know exactly how long it takes for the vapor deposition rate of each of the vapor deposition particle sources to become stable. This makes it possible to know exactly how long it takes to change the vapor deposition rate.

Accordingly, it is possible to determine the capacities, for the vapor deposition material, of the vapor deposition particle sources according to how quick the vapor deposition rate is to be changed to a new vapor deposition rate. That is, by appropriately determining the capacities, for the vapor deposition material, of the vapor deposition particle sources, it is possible to change the vapor deposition rate more quickly.

The vapor deposition particle injection device in accordance with the present invention is configured such that: each of the plurality of vapor deposition particle sources is connected to the injection container via a connecting path; and the connecting path is provided with an individual rate monitor which measures the flow rate of the vapor deposition particles which flow from the each of the plurality of vapor deposition particle sources to the injection container, the flow rate being the vapor deposition rate.

This makes it possible to measure the flow rate of vapor deposition particles in real time, and thus possible to precisely control the vapor deposition rate by the vapor deposition rate control section.

Therefore, even when the vapor deposition rate is to be changed, it is possible to make a quick response such that a new vapor deposition rate is quickly reached. This makes it possible to change the vapor deposition rate more quickly.

The vapor deposition particle injection device in accordance with the present invention is configured such that: each of the plurality of vapor deposition particle sources includes (i) a container for the vapor deposition material and (ii) a heater for heating the vapor deposition material contained in the container; and the Vapor deposition rate control section individually controls, according to the flow rate measured by the individual rate monitor, the heater of the each of the plurality of vapor deposition particle sources.

This makes it possible to control the vapor deposition particle sources independently of each other to generate vapor deposition particles, and thus possible to freely use any of the vapor deposition particle sources according to need.

The vapor deposition particle injection device in accordance with the present invention further includes: a total rate monitor for measuring a vapor deposition rate of vapor deposition particles injected from the injection hole in the injection container, the vapor deposition rate control section controlling, according to the vapor deposition rate measured by the individual rate monitor and the vapor deposition rate measured by the total rate monitor, flow rates of vapor deposition particles which flow from the plurality of vapor deposition particle sources to the injection container.

According to the configuration, the flow rate of vapor deposition particles flowing from each of the vapor deposition particle sources to the injection container is controlled according to the result obtained by the measurement, by the total rate monitor, of the vapor deposition rate of vapor deposition particles injected from the injection hole in the injection container. This makes it possible to control the vapor deposition rate of each of the vapor deposition particle sources in consideration of the vapor deposition rate of vapor deposition particles that are actually deposited.

Therefore, even when the vapor deposition rate is to be changed, it is possible to make a quick response such that a new vapor deposition rate is quickly reached. This makes it possible to change the vapor deposition rate more quickly.

In order to attain the above object, an vapor deposition particle injection device in accordance with the present invention includes: a plurality of vapor deposition particle sources for generating vapor deposition particles in the form of vapor by heating a vapor deposition material; an injection container which (i) is connected to the plurality of vapor deposition particle sources and (ii) has an injection hole from which the vapor deposition particles generated by the plurality of vapor deposition particle sources are injected outward; and a drive control section for controlling operation of the plurality of vapor deposition particle sources, the drive control section sequentially causing the plurality of vapor deposition particle sources to operate while keeping a total vapor deposition rate of the plurality of vapor deposition particle sources constant, the total vapor deposition rate being a total flow rate of vapor deposition particles which flow from the plurality of vapor deposition particle sources to the injection container.

According to the configuration, the plurality of vapor deposition particle sources are sequentially operated while the total vapor deposition rate is kept constant. This makes it possible to use, for film formation, vapor deposition particles having a decreasing or increasing flow rate which are generated while one of the plurality of vapor deposition particle sources is switched to another one of the plurality of vapor deposition particle sources. This makes it possible to use the vapor deposition material more effectively.

The vapor deposition particle injection device in accordance with the present invention is configured such that: each of the plurality of vapor deposition particle sources is connected to the injection container via a connecting path; the connecting path is provided with an open-close member for opening and closing the connecting path; and the drive control section controls the open-close member so that the total vapor deposition rate is kept constant.

According to the configuration, the opening and closing of the open-close member, which is provided to each of the connecting paths connecting the vapor deposition particle sources and the injection container, is controlled. This makes it possible to sharply control the flow of vapor deposition particles. That is, it is possible to sharply control the supply of vapor deposition particles to the injection container by controlling the opening and closing of the open-close member. This makes it possible to stop the injection of vapor deposition particles at the completion of vapor deposition so as to prevent a waste of vapor deposition particles.

This makes it possible to use the vapor deposition material more effectively.

A vapor deposition device in accordance with the present invention includes a vapor deposition source which is the foregoing vapor deposition particle injection device.

The vapor deposition device is capable of responding to a change in the set vapor deposition rate and improving use efficiency of the vapor deposition material.

The vapor deposition device preferably further includes vapor deposition mask for forming a pattern of a vapor-deposited film.

Since the vapor deposition mask is used, it is possible to form a film having a desired pattern.

Further, the film in a predetermined pattern can be used as an organic layer in an organic electroluminescent element. The above vapor deposition device can be suitably used as a device for producing an organic electroluminescent element. That is, the vapor deposition device may be a device for producing an organic electroluminescent element.

A method for producing an organic electroluminescent element with the use of a vapor deposition particle injection device of the present invention includes, for example, (i) a TFT substrate and first electrode preparing step for forming a first electrode on a TFT substrate, (ii) an organic layer depositing step for depositing, over the TFT substrate, an organic layer including at least a luminescent layer, and (iii) a second electrode depositing step for depositing a second electrode, at least one of the steps (ii) and (iii) using, as a vapor deposition source, the vapor deposition particle injection device.

Since the vapor deposition particle injection device of the present invention is used as a vapor deposition source like above, it is possible to quickly carry out a change of the vapor deposition rate which is necessitated by switching between steps. This makes it possible to prevent a waste of vapor deposition particles while the vapor deposition rate is changed, and thus possible to improve material use efficiency.

This makes it possible to reduce costs for production of the organic electroluminescent element, and thus possible to produce an organic EL display device at low cost.

The present invention is not limited to the description of the embodiments above, but may be altered in various ways by a skilled person within the scope of the claims. Any embodiment based on a proper combination of technical means disclosed in different embodiments is also encompassed in the technical scope of the present invention.

### INDUSTRIAL APPLICABILITY

The vapor deposition particle injection device, vapor deposition device and vapor deposition method of the present invention are suitably applicable to, for example, a device and method for producing an organic EL display device which are used in a process of, for example, formation of an organic layer by selective vapor deposition in an organic EL display device.

### REFERENCE SIGNS LIST

1 Organic EL display device
2R, 2G, and 2B Pixel
10 TFT substrate
11 Insulating substrate
12 TFT
13 Interlayer insulating film
13a Contact hole
14 Wire
15 Edge cover
20 Organic EL element
21 First electrode
22 Hole injection layer/hole transfer layer
23R, 23G, and 23B Luminescent layer
24 Electron transfer layer
25 Electron injection layer
26 Second electrode
30 Adhesive layer
40 Sealing substrate
100 Vapor deposition rate control section
101 Heater control section
102 Heater control section
103 Remaining vapor deposition material detecting section
104 Operating section
110 Vapor deposition particle generating section (vapor deposition particle source)
110a to 110d Vapor deposition particle generating section (vapor deposition particle source)
111 Holder
111a Release hole
112 Heater (heater)
112a to 112d Heater (heater)
114 Vapor deposition material
115 Pipe (connecting path)
115a to 115d Pipe (connecting path)
116a to 116d Valve (open-close member)
117, 127 Valve (open-close member)
120 Vapor deposition particle generating section (vapor deposition particle source)
121 Holder
121a Release hole
122 Heater (heater)
124 Vapor deposition material
125 Pipe (connecting path)
130 Pipe (connecting path)
131 Shutter
140 Individual rate monitor
140a to 140d Individual rate monitor
150 Individual rate monitor
160 Total rate monitor
170 Nozzle section (injection container)
171 Injection hole
200 Film formation substrate (film formation subject)
201 Film formation surface
300 Vapor deposition mask
301 Opening
400 Vapor deposition rate control section (drive control section)
401a to 401d Heater control section
402a to 402d Valve drive section
500 Vacuum chamber
501 Vapor deposition particle injection device
502 Vapor deposition particle injection device
503 Vapor deposition particle injection device

1. A vapor deposition particle injection device, comprising:
a plurality of vapor deposition particle sources for generating vapor deposition particles in the form of vapor by heating a vapor deposition material; and
an injection container which (i) is connected to the plurality of vapor deposition particle sources and (ii) has an injection hole from which the vapor deposition particles generated by the plurality of vapor deposition particle sources are injected outward,
assuming that a flow rate of vapor deposition particles which flow from each of the plurality of vapor deposition particle sources to the injection container is a vapor deposition rate of the each of the plurality of vapor deposition particle sources, a target vapor deposition rate of at least one of the plurality of vapor deposition particle sources being reached within a shorter time than a target vapor deposition rate of the other(s) of the plurality of vapor deposition particle sources.

2. The vapor deposition particle injection device according to claim 1, wherein at least one of the plurality of vapor deposition particle sources has a smaller capacity for the vapor deposition material than the other(s) of the plurality of vapor deposition particle sources.

3. A vapor deposition particle injection device, comprising:
a plurality of vapor deposition particle sources for generating vapor deposition particles in the form of vapor by heating a vapor deposition material; and
an injection container which (i) is connected to the plurality of vapor deposition particle sources and (ii) has an injection hole from which the vapor deposition particles generated by the plurality of vapor deposition particle sources are injected outward,
at least one of the plurality of vapor deposition particle sources having a smaller capacity for the vapor deposition material than the other(s) of the plurality of vapor deposition particle sources.

4. A vapor deposition particle injection device according to claim 2, further comprising:
a vapor deposition rate control section for controlling a vapor deposition rate of each of the plurality of vapor deposition particle sources, the vapor deposition rate being a flow rate of vapor deposition particles which flow from the each of the plurality of vapor deposition particle sources to the injection container,
the vapor deposition rate control section concurrently controlling vapor deposition rates of at least two of the plurality of vapor deposition particle sources, one of the at least two of the plurality of vapor deposition particle sources being the at least one of the plurality of vapor deposition particle sources which has a smaller capacity for the vapor deposition material than the other(s) of the plurality of vapor deposition particle sources.

5. The vapor deposition particle injection device according to claim 4, wherein the at least two, of the plurality of vapor deposition particle sources, whose vapor deposition rates are concurrently controlled by the vapor deposition rate control section, contain the same vapor deposition material.

6. The vapor deposition particle injection device according to claim 4, wherein:
each of the plurality of vapor deposition particle sources is connected to the injection container via a connecting path; and
the connecting path is provided with an individual rate monitor which measures the flow rate of the vapor deposition particles which flow from the each of the plurality of vapor deposition particle sources to the injection container, the flow rate being the vapor deposition rate.

7. The vapor deposition particle injection device according to claim 6, wherein:
each of the plurality of vapor deposition particle sources includes (i) a container for the vapor deposition material and (ii) a heater for heating the vapor deposition material contained in the container; and
the vapor deposition rate control section individually controls, according to the flow rate measured by the individual rate monitor, the heater of the each of the plurality of vapor deposition particle sources.

8. A vapor deposition particle injection device according to claim 6, further comprising:
a total rate monitor for measuring a vapor deposition rate of vapor deposition particles injected from the injection hole in the injection container,
the vapor deposition rate control section controlling, according to the vapor deposition rate measured by the individual rate monitor and the vapor deposition rate measured by the total rate monitor, flow rates of vapor deposition particles which flow from the plurality of vapor deposition particle sources to the injection container.

9. A vapor deposition particle injection device, comprising:
a plurality of vapor deposition particle sources for generating vapor deposition particles in the form of vapor by heating a vapor deposition material;
an injection container which (i) is connected to the plurality of vapor deposition particle sources and (ii) has an injection hole from which the vapor deposition particles generated by the plurality of vapor deposition particle sources are injected outward; and
a drive control section for controlling operation of the plurality of vapor deposition particle sources,
the drive control section sequentially causing the plurality of vapor deposition particle sources to operate while keeping a total vapor deposition rate of the plurality of vapor deposition particle sources constant, the total vapor deposition rate being a total flow rate of vapor deposition particles which flow from the plurality of vapor deposition particle sources to the injection container.

10. The vapor deposition particle injection device according to claim 9, wherein:
each of the plurality of vapor deposition particle sources is connected to the injection container via a connecting path;
the connecting path is provided with an open-close member for opening and closing the connecting path; and
the drive control section controls the open-close member so that the total vapor deposition rate is kept constant.

11. A vapor deposition device, comprising a vapor deposition source which is a vapor deposition particle injection device recited in claim 1.

12. A vapor deposition device according to claim 11, further comprising a vapor deposition mask for forming a pattern of a vapor-deposited film.

13. The vapor deposition device according to claim 12, wherein the pattern is an organic layer of an organic electroluminescent element.

14. A vapor deposition device, comprising a vapor deposition source which is a vapor deposition particle injection device recited in claim 3.

15. A vapor deposition device according to claim 14, further comprising a vapor deposition mask for forming a pattern of a vapor-deposited film.

16. The vapor deposition device according to claim 15, wherein the pattern is an organic layer of an organic electroluminescent element.

17. A vapor deposition device, comprising a vapor deposition source which is a vapor deposition particle injection device recited in claim 9.

18. A vapor deposition device according to claim 17, further comprising a vapor deposition mask for forming a pattern of a vapor-deposited film.

19. The vapor deposition device according to claim 18, wherein the pattern is an organic layer of an organic electroluminescent element.
